(19) United States
(12) Patent Application Publication
(10) Pub. No.: US 2022/0139717 A1
(43) Pub. Date: May 5, 2022

(54) LARGE AREA METROLOGY AND PROCESS CONTROL FOR ANISOTROPIC CHEMICAL ETCHING

(71) Applicant: Board of Regents, The University of Texas System, Austin, TX (US)

(72) Inventors: Sidlgata V. Sreenivasan, Austin, TX (US); Akhila Mallavarapu, Austin, TX (US); John G. Ekerdt, Austin, TX (US); Michelle A. Grigas, Austin, TX (US); Ziam Ghaznavi, Austin, TX (US); Paras Ajay, Austin, TX (US)

(21) Appl. No.: 17/433,777

(22) PCT Filed: Feb. 24, 2020
(86) PCT No.: PCT/US2020/019543

§ 371 Date: Aug. 25, 2021

Related U.S. Application Data
(60) Provisional application No. 62/810,070, filed on Feb. 25, 2019.

(51) Int. Cl. H01L 21/306; H01L 21/67

(52) U.S. Cl. CPC H01L 21/30608; H01L 21/67075

(57) ABSTRACT

Various embodiments of the present technology generally relate to semiconductor device architectures and manufacturing techniques. More specifically, some embodiments of the present technology relate to large area metrology and process control for anisotropic chemical etching. Catalyst influenced chemical etching (CICE) can be used to create high aspect ratio semiconductor structures with dimensions in the nanometer to millimeter scale with anisotropic and smooth sidewalls. However, all aspects of the CICE process must be compatible with the equipment used in semiconductor fabrication facilities today, and they must be scalable to enable wafer scale processing with high yield and reliability. This invention relates to metrology and control of etch and CMOS compatible methods of patterning the catalyst and removing it without damaging the etched structures.

### CROSS-REFERENCE TO RELATED APPLICATIONS

This application claims priority to U.S. Provisional Application Ser. No. 62/810,070 filed Feb. 25, 2019, which is incorporated herein by reference in its entirety for all purposes.

### TECHNICAL FIELD

Various embodiments of the present technology generally relate to semiconductor device architectures and manufacturing techniques. More specifically, some embodiments of the present technology relate to large area metrology and process control for anisotropic chemical etching.

### BACKGROUND

Semiconductor manufacturing of various types of transistors, memories, integrated circuits, photonic devices and other semiconductor devices have led to the proliferation of modern computing devices and other electronic systems. For example, computers, mobile phones, automobiles, consumer electronics, and the like are all a direct product of advancements in semiconductor manufacturing. An integral part of fabrication of these devices is etch and pattern transfer. Dry plasma etching processes, which are used in the semiconductor industry for anisotropically etching highly controlled nanopatterns, require expensive vacuum equipment and cannot retain cross-section shape easily when patterning high aspect ratios. They suffer from etch challenges such as Aspect Ratio Dependent Etching (ARDE) and etch taper. Catalyst influenced chemical etching (CICE) is a viable alternative, and is described in this document.

### SUMMARY

Various embodiments of the present technology generally relate to semiconductor device architectures and manufacturing techniques. More specifically, some embodiments of the present technology relate to large area metrology and process control for anisotropic chemical etching. Catalyst influenced chemical etching (CICE) can be used to create high aspect ratio semiconductor structures with dimensions in the nanometer to millimeter scale with anisotropic and smooth sidewalls. However, all aspects of the CICE process must be compatible with the equipment used in semiconductor fabrication facilities today, and they must be scalable to enable wafer scale processing with high yield and reliability. This invention relates to metrology and control of etch and CMOS compatible methods of patterning the catalyst and removing it without damaging the etched structures.

The catalysts currently used in CICE are not CMOS compatible and use non-standard methods of patterning that suffer from low yield, such as lift-off. Removal of the catalysts after the etch is completed while ensuring that the etched features are unharmed is also not present today. Various embodiments of the present technology use industry standard processes to pattern and etch catalysts for CICE. The process windows for the catalysts are also expanded using electric fields. Methods of detecting and avoiding process excursions are also listed.

In some embodiments, an apparatus for catalyst influenced chemical etching is provided. The apparatus can include a process chamber, one or more actuators, a control system, a light source, and/or a rinsing station. The process chamber can be configured to house a semiconductor wafer. The one or more actuators configured to control environmental properties within the process chamber. The control system can be configured to control rate of etching of the semiconductor wafer by adjusting the one or more environmental properties via the one or more of actuators. The light source can be configured to illuminate one or both sides of the semiconductor wafer. The rinsing station can be configured to remove the etchant.

Some embodiments provide for a method for improving reliability of catalyst influenced chemical etching. A semiconducting material can be provided, and a catalyst layer can be patterned on a surface of the semiconducting material. The patterned catalyst layer can be exposed to an etchant and to a time-varying electric field. In some embodiments, the patterned catalyst layer, the etchant and the electric field cause etching of semiconducting material to form vertical nanostructures. One or more layers of porosity can be created as the etch progresses, such that the porous layers enhance etchant diffusion during etch of high aspect ratio structures.

Some embodiments provide techniques for improving reliability of catalyst influenced chemical etching. A semiconducting material can be provided, and a catalyst layer can be patterned on a surface of the semiconducting material. In some embodiments, the pattern can include one or more lithographic links. The patterned layer can be exposed to an etchant such that the lithographic links in the patterned catalyst layer enhance etchant diffusion during etch of high aspect ratio structures.

Various embodiments provide methods of patterning a catalyst for catalyst influenced chemical etching. In some embodiments, a substrate can be patterned with lithographic structures. The surface of the substrate can be exposed in areas without the lithographic structures. A catalyst can be selectively deposited on the exposed substrate surface. The substrate and catalyst can be exposed to an etchant.

In some embodiments, methods of patterning a catalyst for catalyst influenced chemical etching are provided. These methods can include depositing a catalyst on a substrate. In some embodiments, the catalyst can be patterned with lithographic structures. The lithographic structures are used as a mask for etching of the catalyst material. These methods can also include exposing the substrate and the catalyst to an etchant.

Some embodiments provide methods of removing catalyst material after catalyst influenced chemical etching. These methods can include creating, using a catalyst, high aspect ratio structures using catalyst influenced chemical etching. The catalyst can lie at the bottom of the high aspect ratio structures. The methods can further include removing the catalyst material without substantially affecting the high aspect ratio structures.

Some embodiments provide methods for etching semiconducting material. These methods can include providing a semiconducting material and patterning a catalyst layer on a surface of the semiconducting material. The catalyst layer comprises a plurality of features. The patterned catalyst layer can then be exposed to an etchant. The patterned catalyst layer and the etchant can cause etching of semiconducting material to form fabricated structures corresponding; to the plurality of features. The catalyst material may contain ruthenium.

Some embodiments provide methods for etching semiconducting material. These methods can include providing a semiconducting material and patterning a catalyst layer on a surface of the semiconducting material. The catalyst layer may include a plurality of features. The patterned catalyst layer can be exposed to an etchant. The patterned catalyst layer and the etchant can cause etching of semiconducting material to form fabricated structures corresponding to the plurality of features. The catalyst material may be an alloy of two or more materials.

In some embodiments, methods for etching semiconducting material can include providing a semiconducting material, wherein the material has at least one doping type and/or concentration. The methods can also include patterning a catalyst layer on a surface of the semiconducting material. The catalyst layer may include a plurality of features. The patterned catalyst layer can be exposed to an etchant. The patterned catalyst layer and the etchant can cause etching of semiconducting material to form fabricated structures corresponding; to the plurality of features. The doping of at least one layer of the semiconducting material can be modified.

In some embodiments, methods for preventing substantial collapse of high aspect ratio semiconducting structures by catalyst influenced chemical etching are provided. The methods can include creating a support structure by depositing a material on two or more uncollapsed semiconductor structures. In addition, the methods can include exposing the support structure to an etchant to form higher aspect ratio semiconductor structures with the material increasing the critical height of features before collapse, to prevent substantial collapse of the higher aspect ratio the semiconducting structures.

Embodiments of the present technology also include computer-readable storage media containing sets of instructions to cause one or more processors to perform the methods, variations of the methods, and other operations described herein.

While multiple embodiments are disclosed, still other embodiments of the present technology will become apparent to those skilled in the art from the following detailed description, which shows and describes illustrative embodiments of the technology. As will be realized, the technology is capable of modifications in various aspects, all without departing from the scope of the present technology. Accordingly, the drawings and detailed description are to be regarded as illustrative in nature and not restrictive.

### BRIEF DESCRIPTION OF THE DRAWINGS

Embodiments of the present technology will be described and explained through the use of the accompanying drawings.

FIG. 1 illustrate an example of diamond cross-section nanowires etched with gold (Au) catalyst in accordance with some embodiments of the present technology.

FIG. 2 illustrates an example of a circular cross-section nanowires etched with Palladium (Pd) catalyst in accordance with various embodiments of the present technology.

FIG. 3 illustrates an example of circular cross-section nanowires etched with Ruthenium (Ru) catalyst in accordance with one or more embodiments of the present technology.

FIG. 4 illustrates an example of circular cross-section nanoholes etched with Platinum (Pt) catalyst in accordance with one or more embodiments of the present technology.

FIG. 5 illustrates an example of a set of steps that may be used in patterning a catalyst using selected ALD in accordance with some embodiments of the present technology.

FIG. 6 illustrates an example of a process flow for selective ALD after photolithography in accordance with one or more embodiments of the present technology.

FIG. 7 illustrates an example of patterning of catalyst using ALE in accordance with some embodiments.

FIG. 8 illustrates an example of patterning of a catalyst using lift-off in accordance with some embodiments.

FIG. 9 illustrates an example of patterning catalyst without lift-off according to various embodiments of the present technology.

FIG. 10 illustrates an example of patterning of a catalyst by depositing catalyst material on etched features showing discontinuity in pattern according to various embodiments of the present technology.

FIG. 11 illustrates an example of ALE of catalyst material in accordance with some embodiments of the present technology.

FIG. 12 illustrate an example of access of catalyst for ALE in high aspect ratio trenches in accordance with one or more embodiments of the present technology.

FIG. 13 illustrates an example of a process flow with an embed catalyst according to some embodiments of the present technology.

FIG. 14 illustrates an example of using combinatorial material deposition of catalyst alloys for CICE in accordance with some embodiments of the present technology.

FIG. 15 illustrates an example of a process for extending critical aspect ratio of features etched with CICE in accordance with some embodiments of the present technology.

FIG. 16 illustrates an example of the design of a yield monitor to detect etch depth using programmable collapse according to some embodiments of the present technology.

FIG. 17 illustrates an example of a 3D NAND Flash integration scheme using CICE to create the structures, where the final conductor and insulator layer top-down cross-sections are shown in accordance with various embodiments of the present technology.

FIGS. 18-19 illustrate example of process flow depicting alternative approaches to making 3D NAND Flash devices with improved conductance of the conductor layers in accordance with various embodiments of the present technology.

FIG. 20 illustrates examples of the initial catalyst pattern for CICE of 3D NAND flash architectures in accordance with various embodiments of the present technology.

FIG. 21 illustrates an example of a lithography process flow to create catalyst patterns in accordance with various embodiments of the present technology.

FIG. 22 illustrates an example of a CICE tool with different subsystems, in accordance with various embodiments of the present technology.

The drawings have not necessarily been drawn to scale. Similarly, some components and/or operations may be separated into different blocks or combined into a single block for the purposes of discussion of some of the embodiments of the present technology. Moreover, while the technology is amenable to various modifications and alternative forms, specific embodiments have been shown by way of example in the drawings and are described in detail below. The intention, however, is not to limit the technology to the particular embodiments described. On the contrary, the technology is intended to cover all modifications, equivalents, and alternatives falling within the scope of the technology as defined by the appended claims.

### DETAILED DESCRIPTION

Various embodiments of the present technology generally relate to semiconductor device architectures and manufacturing techniques. More specifically, some embodiments of the present technology relate to large area metrology and process control for anisotropic chemical etching. Catalyst influenced chemical etching (CICE) is a fabrication process used to create high aspect ratio semiconductor structures with anisotropic and smooth sidewalls. A catalyst is patterned on a semiconductor substrate and exposed to an etchant. The catalyst sinks into the substrate as the material under it is selectively etched away by the etchant. Dry plasma etching processes which are used in the semiconductor industry for creating highly controlled nanopatterns, require expensive vacuum equipment and suffer from etch challenges such as Aspect Ratio Dependent Etching (ARDE) and etch taper when fabricating high aspect ratio structures. CICE can overcome these challenges in plasma etching for semiconducting substrates such as silicon. This etch process can be used to fabricate semiconductor devices such as transistors, DRAM and 3D NAND Flash.

However, all aspects of the CICE process must be compatible with the equipment used in semiconductor fabrication facilities today, and they must be scalable to enable wafer scale processing with high yield and reliability. Various embodiments of the present technology relate to large area metrology of CICE and CMOS compatible methods of patterning the catalyst and removing it without damaging the etched structures, thereby enabling adoption into the semiconductor industry.

Various embodiments of the present technology provide for a wide range of technical effects, advantages, and/or improvements to semiconductor manufacturing processes, systems and components. For example, various embodiments include one or more of the following technical effects, advantages, and/or improvements: 1) lower power consumption, improved performance and/or increased memory density of computing and memory devices; 2) increased throughput and yield for fabrication of devices; 3) use of unconventional and non-routine design rules to design templates and photomasks for catalyst patterns for CICE; 4) new methods of large area, high throughput patterning of catalyst films for CICE, 5) Improved tool sensors and actuators for high yield etch using CICE; 6) changing the manner in which semiconductor device fabrication masks are designed; 7) changing the manner in which catalysts for CICE are patterned and etched; ad/or 8) changing the catalyst materials and/or substrates used for CICE.

In the following description, for the purposes of explanation, numerous specific details are set forth in order to provide a thorough understanding of embodiments of the present technology. It will be apparent, however, to one skilled in the art that embodiments of the present technology may be practiced without some of these specific details.

The techniques introduced here can be embodied as special-purpose hardware (e.g., circuitry), as programmable circuitry appropriately programmed with software and/or firmware, or as a combination of special-purpose and programmable circuitry. Hence, embodiments may include a machine-readable medium having stored thereon instructions which may be used to program a computer (or other electronic devices) to perform a process. The machine-readable medium may include, but is not limited to, floppy diskettes, optical disks, compact disc read-only memories (CD-ROMs), magneto-optical disks, ROMs, random access memories (RAMs), erasable programmable read-only memories (EPROMs), electrically erasable programmable read-only memories (EEPROMs), magnetic or optical cards, flash memory, or other type of media/machine-readable medium suitable for storing electronic instructions.

The phrases “in some embodiments,” “according to some embodiments,” “in the embodiments shown,” “in other embodiments,” and the like generally mean the particular feature, structure, or characteristic following the phrase is included in at least one implementation of the present technology, and may be included in more than one implementation. In addition, such phrases do not necessarily refer to the same embodiments or different embodiments.

The following patents and patent applications are incorporated herein in their entirety for all purposes: 1) Sreenivasan, Sidlgata V., Akhila Mallavarapu, Shrawan Singhal, Lawrence Dunn and Brian Gawlik “Forming Three-Dimensional Memory Architectures Using Catalyst Mesh Patterns,” U.S. Provisional Patent Application No. 62/591,326 filed Nov. 28, 2017; 2) Sreenivasan, Sidlgata V. and Akhila Mallavarapu “Multilayer Electrochemical Etch process for Semiconductor Device Fabrication,” U.S. Provisional Patent Application No. 62/665,084 filed on May 1, 2018; 3) Sreenivasan, Sidlgata V. and Akhila Mallavarapu “Catalyst-Based Electrochemical Etch Process for Semiconductor Device Fabrication,” U.S. Provisional Patent Application No. 62/701,049 filed on Jun. 20, 2018; 4) Sreenivasan, Sidlgata V., Akhila Mallavarapu, Shrawan Singhal and Lawrence Dunn “Catalyst Assisted Chemical Etching Technology: Applications In Semiconductor Devices,” U.S. Provisional Patent Application No. 62/729,361 filed on Sep. 10, 2018; 5) Sreenivasan, Sidlgata V., Akhila Mallavarapu, Shrawan Singhal, Lawrence Dunn and Brian Gawlik “Catalyst Influenced Pattern Transfer Technology,” U.S. Patent Publication No. 2018/060176 filed on Nov. 9, 2018; 6) Sreenivasan, Sidlgata V., Akhila Mallavarapu, John Ekerdt, Michelle Grigas, Ziam Ghaznavi and Paras Ajay “Large Area Metrology and Process Control for Anisotropic Chemical Etching,” U.S. Provisional Patent Application No. 62/810,070 filed on Feb. 25, 2019; 7) Sreenivasan, Sidlgata V., Akhila Mallavarapu, Jaydeep Kulkarni, Michael Watts and Sanjay Banerjee “Three-dimensional SRAM architectures using Catalyst Influenced Chemical Etching,” U.S. Provisional Patent Application No. 62/847,196 filed on May 13, 2019; and 8) Sreenivasan, Sidlgata V. and Akhila Mallavarapu “Low Loss, High Yield Waveguides for Large-Scale Integrated Silicon Photonics,” U.S. Provisional Patent Application No. 62/911,837, filed Oct. 7, 2019.

CICE is a catalyst based etching method that can be used on semiconductors such as Si, Ge, SiₓGe₁₋ₓ, GaN, InP, GaAs, InAs, GaP, InGaS, InGaP, SiC etc. as well as multilayers of the semiconductors. The semiconductors can be on both rigid and flexible substrates such as silicon wafers, glass or quartz wafers, sapphire wafers, polymer films, stainless steel films, etc. Semiconductors grown or deposited on the various substrates such as silicon on metal films such as on Hastelloy steel, germanium or GaAs on Hastelloy steel, silicon on polymer films. The semiconductor material may be crystalline, poly-crystalline or amorphous. Gao et al. “High-Performance Flexible Thin-Film Transistors Based on Single-Crystal-like Silicon Epitaxially Grown on Metal Tape by Roll-to-Roll Continuous Deposition Process.” ACS Applied Materials & Interfaces 8, no. 43 (Nov. 2, 2016): 29565-72 is incorporated herein by reference in its entirety for all purposes.

CICE uses a catalyst to etch semiconducting substrates and it has been used to fabricate high aspect ratio features with patterning techniques such as photolithography, electron beam lithography, nanosphere lithography, block co-polymers, laser interference lithography, colloidal lithography, double patterning, quad patterning, nanoimprint lithography and anodized aluminum oxide (AAO) templates to pattern the catalyst. The catalyst can be used in conjunction with etch-retarding materials such as polymer, Cr, etc.

In some embodiments, this setup can be immersed in a solution containing an etchant (e.g., fluoride species HF, NH₄F, Buffered HF, H₂SO₄, H₂O) and an oxidant (H₂O₂, V₂O₅, KMnO₄, dissolved oxygen, etc.). Other chemicals such as alcohols (ethanol, isopropyl alcohol, ethylene glycol), materials to regulate etch uniformity (surfactants, soluble polymers, dimethyl sulfoxide-DMSO), solvents (DI water, DMSO etc.), and buffer solutions can also be included in the etch composition. The chemicals used can depend on the semiconducting substrate to be etched. Non-aqueous etchants can also be used if needed. The etchants can be in liquid or vapor phase. An embodiment of such an etchant for silicon substrates comprises DI H₂O, H₂O₂, Ethanol and HF.

Metals (e.g., Ag, Au, Pd, Pt, Co, Cu, W, Ru, Ir, Rh), compounds such as TiN, TaN, RuO₂, IrO₂ and other conductive metal oxides and nitrides, graphene, carbon etc. can act as catalysts for CICE. The mechanism for the CICE process for etching Si may involve the reduction of the oxidant by a catalyst, thereby creating positively charged holes h⁺. These holes are then injected through the metal to the metal-semiconductor interface thereby oxidizing the semiconductor underneath the metal. The oxidized silicon is dissolved by the fluoride component of the etchant that diffuses from the sides of and through the catalyst and the soluble products diffuse away. For CICE of silicon with HF and H₂O₂, this redox reaction can also produce hydrogen gas. The variable n=2 to 4 is determined by the ratio of oxidant to HF which determines the etch regime that occurs:

Si+n/2H₂O₂+6HF→H₂SiF₆+nH₂O+4−n/2H₂↑

CICE research has focused mostly on metals such as Au and Ag, which are not CMOS compatible. However, this process can be extended to catalysts such as Pt, Ru and Pd, which can then be used to make semiconductor devices such as transistors and memory arrays.

CICE is a superset of a process called Metal Assisted Chemical Etching (MACE). Apart from metals, there are certain non-metallic catalysts such as graphene or ceramics (TiN, TaN etc.) that can also be potentially be used as catalysts. Further, while the catalysts usually locally assist in the chemical etching by digging into the substrate in the presence of etchants and oxidants, they can also locally inhibit the etch, as in the case of InP. To encompass all such processes, various embodiments refer to the process Catalyst Influenced Chemical Etching (CICE).

However, CICE does not currently have large area precise etch depth control and wafer scale fabrication capability. Discontinuous catalyst features tend to wander during the CICE process and cause defects. Catalysts used are not easy to etch with plasma or wet chemical etch without re-deposition or undercut. Lift-off processes, currently used to pattern noble metal catalyst, suffer from high defectivity. This invention shall enable patterning of catalyst material with arbitrary nanopatterns with feature sizes ranging from millimeter to nanometer.

In embodiments where the substrate used in the CICE process is not resistant to the CICE etch chemicals, such as with quartz wafers or metal substrates such as Hastelloy, the backside of the substrate is protected by coating it with etch resistant materials such as polymers, and/or by exposing only the front of the surface to the etchant. Seals such as O-rings can be used to protect the backside of the wafer, or in the case of flexible metal films, a roll-to-roll system can be used where the rollers are vertical, and the roll between the rollers is sprayed on only one side with the etchant chemical. Alternatively, surface tension can be used to contain the etchant to only one side of the roll.

### CICE Applications

CICE can be used to create nanostructures of bulk material or alternating layers of material such as superlattices. CICE of bulk material can be used in devices such as finFETs and nanowire sensors. Superlattice nanostructures have applications in 3D NAND Flash memory devices and nanosheet transistors. Superlattices can be created by performing CICE on bulk semiconducting substrates with time-varying electric fields, or on substrates with alternating layers of semiconducting material differing in doping concentration, material, dopant type, etc. These nanostructures with defined morphologies can be used for many applications as described below.

Transistors: Plasma etching for fabrication of fins has a variety of process challenges such as precision etching, etch taper, collapse, erosion and structural integrity, and sidewall damage. This affects device performance of the transistors. High aspect ratio etch with low sidewall damage for sub-10 nm critical dimension fins can be achieved with CICE. The etch taper angle creates further challenges as it limits the maximum height of the fin at a certain fin width. To increase the height of the fin, the width of the fin has to be increased, which reduces the transistor packing density.

3D NAND Flash: The ITRS Roadmap for 3D NAND Flash predicts that the number of memory layers will increase steadily from 48 layers in 2016 to 512 in 2030, at 80 nm half-pitch. This requires significant development in highly anisotropic (˜900) high aspect ratio etching of layers of alternating material. The current plasma etching methods involve expensive and low throughput alternating deposition and etch steps to ensure that this anisotropy and selectivity is maintained. A plasma etch taper angle of anything less than 90 degrees limits the maximum number of tier stacking that can be reliably achieved. Also, due to a non-zero taper, the channels etched by plasma etching limit the number of layers that can reliably be scaled as the bottom-most layer has a much smaller critical dimension than the lithographically defined top layer. A workaround to overcome this limitation by stacking multiple wafers with 64 memory layers each is inefficient, expensive and increases the device volume. Separate lithography and etch steps are required for the circular channels and the rectangular slits, as different geometries cannot be etched simultaneously and reliably with plasma etching due to Aspect Ratio Dependent Etch (ARDE). CICE aims to solve that by enabling an inexpensive high aspect ratio etch with high selectivity and anisotropy that can be extended to future demands of 3D NAND Flash.

DRAM: With scaling of Dynamic Random-Access Memory (DRAM) transistors and capacitors in the lateral dimension, the aspect ratio for the capacitors must be increased to maintain the minimum capacitance threshold required for optimal functioning of DRAM cells. DRAM capacitors can be created as trenches or stacks. Trench capacitors suffer from plasma etch taper limitations to the maximum depth of the capacitor, and stacked capacitors suffer from limitations to maximum height due to collapse as well as etch taper.

All the above applications can benefit from CICE as it can etch high aspect ratio nanostructures without etch taper limitations. Other applications such as gas sensors with high-aspect-ratio nanowires, optical devices, or the like can also be realized with the CICE process.

Patent “Catalyst Influenced Pattern Transfer Technology” PCT/US2018/060176 is incorporated herein by reference in its entirety for all purposes.

### Etch Uniformity

The etch depth, porous layer thicknesses, anisotropy as well as etch direction of etched structures must be uniform across the wafer. To ensure uniformity, various components of the CICE process must be controlled. For example, in some embodiments, etchant concentration can be done by monitoring and controlling the etchant concentration using two techniques: a) Conductivity measurement and/or b) Refractive Index measurement. In conductivity measurement, Hydrofluoric Acid (HF) has a linear dependence between concentration and conductivity. In refractive Index measurement, an optical metrology system will measure the Refractive Index (RI) via a reflection-type geometry using an optical window in contact with the solution, thus avoiding turbidity, diffraction and absorption. Additionally, to ensure etchant concentration uniformity across the wafer, a diffuser can be used for uniform distribution of etchant across the wafer surface, a stirrer can be used to stir the etchant, the etchant can be recirculated during the etch using pneumatic pumps, and/or the wafer can be spun using a wafer chuck.

Electric fields can be used for various functions during the CICE process such as for making alternating porous/non-porous layers, preventing wandering of the catalyst during etch, maintaining uniformity across the wafer and detecting etch depth variations in a die, die-to-die variations, and center-to-edge variations. Electric field parameters such as current, voltage, resistance, capacitance, waveform frequency, duty cycle, amplitude, distance between electrodes etc. are used both to detect changes in the etch state as well as control the porosities of the alternating layers while preventing wandering of the catalysts. Applying electric fields across the substrate, both locally and globally, requires designing the tool and process to ensure compatibility with different CMOS processing equipment and constraints such as front and back contact, edge width contact, electric back contact materials etc.

Additionally, an ohmic contact must be created on the back of the wafer to ensure uniform electric field across the wafer. The ohmic contact can be created by doping the back of the wafer with a higher concentration of dopants (in the excess of 1019 cm-3), deposition a metal and subsequently annealing it, rubbing GaIn eutectic (e.g. 24% ln, 76% Ga) on the backside of the sample, or providing the backside with an electrolyte contact which is illuminated thereby creating photogenerated electron-hole pairs. In particular, to produce significant currents across moderately doped wafers, the reverse biased junction has to be illuminated, i.e. the anode (for p-type substrates) or the cathode (for n-type substrates) should be illuminated. The intensity of light may be modulated. Thus, the design of the CICE tool must account for the transmission of light through the components, electrodes and electrolyte onto the back of the wafer for creating an ohmic contact, and onto the front of the wafer for visible wavelength optical metrology. (See, e.g., “Lehmann, Volker. Electrochemistry of Silicon: Instrumentation, Science, Materials and Applications. Wiley, 2002” which is hereby incorporated by reference in its entirety for all purposes.)

The electrolytes on either side of the wafer need not be the same as the etchant. On the front side of the wafer, the electrolyte is same as the CICE etchant, i.e., it comprises one or more of: a chemical to etch the desired material (e.g., fluoride species HF, NH₄F, Buffered HF, H₂SO₄, H₂O), an oxidant (H₂O₂, V₂O₅, KMnO₄, dissolved oxygen, etc.), alcohols (ethanol, isopropyl alcohol, ethylene glycol), materials to regulate etch uniformity (surfactants, soluble polymers, dimethyl sulfoxide-DMSO), solvents (DI water, DMSO etc.), and buffer solutions.

In one embodiment, the etchant on the front side of the wafer comprises HF and IPA. In another embodiment, it comprises HF and Ethanol. In a further embodiment, the etchant comprises HF, H₂O₂, DI water and Ethanol. The electrolyte on the back of the wafer may comprise a chemical that is identical to the electrolyte on the front side of the wafer. Alternatively, it may comprise other chemicals such as diluted H₂SO₄, polymer-based electrolytes (e.g. a mixture of poly vinyl alcohol (PVA) or poly lactic acid (PLA) and H₂SO₄), dissolved salts such as ammonium sulphate, etc. In this case the materials on the back of the wafer such as a wafer chuck, thermal and electrical actuators, optical sensors, electrodes etc. may be of materials that are resistant to the alternate electrolyte instead of to the etchant chemicals, which increases the choice of materials that can be used. In one embodiment, the polymer-based electrolyte is made by mixing PVA powder, H₂SO₄ powder and DI water, which is then injected onto the back of the wafer. After etch, the front and back of the wafer are rinsed with one or more of the following: acetone, isopropyl alcohol, methanol, and/or DI water. The wafer may also be cleaned on the front and back using an oxygen plasma.

Some embodiments can use various techniques of preprocessing of the substrate. In some embodiments, prior to the CICE process, the wetting properties of the etchant chemicals on the catalyst patterned substrate can be modified to make it more hydrophobic or hydrophilic. This helps improve the uniformity of the etch process by ensuring that the initiation of the etch starts in all locations of the substrate at the same time. Exposing the substrate to vapor HF, Piranha (sulfuric acid and hydrogen peroxide in different ratios), buffered oxide etchant, hydrofluoric acid, etc.; and/or rinsing it with DI water, isopropyl alcohol, acetone, etc., and then drying it to prevent water stains can improve wetting of the etchant on the substrate. The pre-processing step may also be via plasma activation using oxidizing plasmas such as oxygen, carbon dioxide plasma, or hydrogenating plasmas such as hydrogen, ammonia plasma. A helium, nitrogen or argon plasma can also be used.

In one embodiment, the pre-processing of the substrate involves using a silicon oxide layer with thickness between 1 nm and 500 nm, followed by deposition and patterning of a catalyst and subsequent CICE etch. The presence of the oxide layer may enhance etch uniformity.

Temperature can influence CICE etch rates. For instance, it has been demonstrated in literature that the etch rates of CICE depend on the temperature of the etchant, and drop off exponentially near 0° C. (Ref: Backes, A. et al., 2016. Temperature Dependent Pore Formation in Metal Assisted Chemical Etching of Silicon. ECS Journal of Solid State Science and Technology, 5(12), pp. 653-P656 is hereby incorporated by reference in its entirety for all purposes.) Various embodiments take advantage of this property by locally controlling the etch temperature by maintaining the global etchant temperature near zero degrees using coolants such as liquid nitrogen and dry ice, and locally modifying the temperature of the substrate. This can be done using thermal chucks, micromirrors or electrodes near the wafer that can locally heat the solution. Alternatively, etchant temperatures can be controlled locally by using individual wells for each die which are filled with finite and temperature-controlled etchant volume and are pumped out or circulated. In some embodiments, the temperature can be mapped with precision across the wafer using thermal cameras, thermocouples, and the like.

### Optical Metrology and Illumination for Etch Control—

A crucial aspect of the CICE process is etch depth uniformity and control. The etch depth as well as any porous layers that are formed during CICE can be measured and characterized using many destructive and non-destructive methods such as Scanning Electron Microscopy (SEM), Transmission Electron Microscopy (TEM), Atomic Force Microscopy (AFM), Optical Scatterometry, Ellipsometry, small angle X-ray scatterometry, through focus Scanning Optical Microscopy (TSOM), Helium Ion microscopy, proton microscopy, etc.

For in-situ measurements of the etch profiles, the CICE tool design must ensure that the front of the substrate as well as the back can be imaged using one or more wavelengths of light. The design of the CICE tool must account for the transmission of light through the components and electrolyte onto the back of the wafer for creating an ohmic contact, and onto the front of the wafer for optical metrology. This can be accomplished by using sapphire windows on each side of the process chamber, or using optic fiber cables. The sapphire windows and/or optic fiber components may be coated with etchant resistant materials such as Teflon or Aluminum Oxide, while maintaining the transparency of the substrate. The electrodes can be made of platinum wires, platinum meshes, Indium Tin oxide with etchant resistant coating, doped silicon wafers with optional coating of etchant resistant material such as carbon, diamond, aluminum oxide, Cr, etc. The etchant resistant material can further be doped to improve conductivity. The geometry of the electrode can be optimized to ensure uniform electric fields while also ensuring light passes through, such as with an annular ring. Mirrors such as chrome-coated silicon or thin chrome plates may also be used to direct light onto the top of the substrate. One or more electrodes can be used on each side of the wafer in the process chamber.

Optical metrology can be used in-situ to examine the substrate during the etch process, since the optical properties of silicon nanostructures lead to a wide spectrum of colors and changes in hue. The optical properties of Si nanostructures have previously been studied down to the single-nanowire level. The optical properties of Si nanostructures of variable geometries lead to a wide spectrum of colors under white light illumination. In our preliminary experiments with CICE, Si nanowire samples exhibit profound changes in hue during the CICE etch. Since the pitch and diameter of the nanowires remain relatively fixed, observing changes in the hue of samples is a useful indicator of the height of the nanowires, and thus the etch depth. Changes in hue can be characterized by measuring the reflectance of the sample as a function of the spectral content of the light being. Additionally, in nanostructures with porous layers, photoluminescence and thermoluminescence of porous silicon, as well as optical properties of alternating layers of differently-porous silicon (such as in rugate filters and brag reflectors) can be exploited to determine etch properties such as layer thickness, porosity, pore size, etch depth variation, etc.

An optical imaging system will be used to measure the reflectance over large sample areas in real-time. The samples will be illuminated with light with known spectral content. The light can be white light, colored light, single wavelength, in a narrow or wide spectral band, etc. A camera can then image the samples reflecting this light. The camera may be monochrome, color (RGB), multi-spectral, hyperspectral, etc. Multi-megapixel resolutions found in modern cameras make it possible to observe millions of points on a sample simultaneously. Video framerates enable in-situ real-time measurement. Each image can be divided by an image of a reference to calculate reflectance images of the samples or used as they are. An image processing algorithm will determine process completion and gather data about uniformity of CICE both within samples and sample to sample.

Visible wavelengths of light from the backside of the wafer cannot detect the etch depth during CICE. Infrared (IR) spectroscopy can be used instead, as is it a rapid, non-destructive and in-situ method of etch state detection. Silicon is transparent in IR wavelengths, while the catalyst is not. This differentiation can be used to determine both the etch rate and the etch depth at any particular instance of the CICE process. The images acquired using IR metrology from the back of the wafer, along with the visible light images acquired from the front of the wafer during etch can be used to create a 3D image of the etch front and the substrate before, during, and after the etch. This can be used to detect process excursions and progress of the etch in situ. The snapshots are acquired at regular time intervals, wherein the time interval can be smaller than a minute and as small as 1 ms. These snapshots when taken at higher than 100 kHz, can be used for real-time process control, wherein the feedback is used to adjust or refine one of the following control variables locally and/or globally: electric fields, temperature, etchant concentration, magnetic field, illumination, vapor pressure, etc. Such snapshots could also be used at the end of etching of the wafer to reconstruct the 3D geometry of the final etched substrate which could include non-porous, porous, and multiple materials (SiGe) etc. Such information can be used for quality control or for automated process control where the feedback is done on a wafer-to-wafer basis.

Additionally, etch uniformity during the CICE process also depends on the resistance of the contact between an electrode and substrate if CICE uses an electric field. Illumination of the back side of the substrate with light of optimized wavelengths and intensities improves the uniformity of the etch.

### Postprocessing of the Substrate

The substrate doping and dopant concentration is selected to optimize the morphology of the structures etched with CICE. The substrate may comprise a layer of silicon with the optimized doping, or the entire substrate may be of the optimized doping concentration. In one embodiment, and the substrate is undoped silicon. In another embodiment, the substrate is moderately doped n-type silicon with phosphorus dopant having a resistivity of 0.01-0.1 ohm-cm. Other embodiments include lightly doped n-type silicon with phosphorus and/or arsenic dopants, p-type silicon with boron dopants that are lightly doped, moderately doped, heavily doped, or degenerately doped. N-type silicon with phosphorus dopants that are lightly doped, moderately doped, heavily doped, or degenerately doped.

After CICE, the catalyst is removed and the etched features and substrate can be doped using ion implantation, annealing, diffusion, etc. to create structures with application-specific doping type and concentration. In one embodiment, etched structures in a highly doped n-type layer can be modified using boron implantation and annealing to change the doping to undoped or lightly p-doped. In another embodiment, etched structures in undoped silicon are then doped to modify their doping to lightly or heavily p-doped or n-doped silicon.

### Vapor Etching and Control

CICE can be performed with etchants in vapor state. An apparatus for vapor based CICE may comprise a thermal chuck for control of local substrate temperatures and a means for monitoring of vapor pressure of each component of the etchant vapor. An electric field may also be applied in the form of a plasma. In some embodiments, pulse H₂O₂ vapor and HF vapor, pulse H₂O₂ liquid and HF liquid, pulse H₂O₂ vapor and HF liquid, or pulse H₂O₂ vapor and HF liquid can be used. H₂O₂, Plasma and fluoride ion flow/pressure can be alternated for alternating porosities. Using stronger oxidant for porous layers and weaker oxidant for non-porous layers. Apparatus for vapor based CICE is similar to vapor etching tools such as vapor-HF. Thermal chucks with local temperature control along with optical metrology can be used to control the etch depth variations for vapor based CICE.

### Magnetic Field Assisted CICE

Magnetic materials such as Ni, Co, Fe can be used in the catalyst to perform CICE. Based on their resistance to the CICE etchant, the metals may be used as standalone catalysts or they may be encased in other catalyst materials such as Pd, Pt, Au, Ru etc. A magnetic field can be used to direct the catalyst patterns as the etch progresses, and can prevent etch depth variations, or function as an etch-stop method.

### Catalyst Patterning Processes

Wafer-scale patterning of catalyst material is an essential aspect of the CICE process. Typical patterning methods such as plasma etching and chemical etching do not apply to the catalysts used in CICE. The catalyst materials are typically noble metals, which do not form volatile by-products for plasma etching. Additionally, chemical etching of such metals can attack lithographic patterns and substrate materials. Various embodiments provide for alternate methods for creating catalyst patterns.

### Catalyst Material

The catalyst material should be CMOS-compatible to prevent deep-level defects in silicon. Deep-level defects appear when metals such as Au and Cu are processed at high temperature. As CICE is a room- to low-temperature process, the effect of such defects might be minimal. The catalyst can be one or more of the following—Au, Ag, Pt, Pd, Ru, Ir, Rh, W, Co, Cu, Al, RuO₂, IrO₂, TiN, TaN, graphene, etc. The effect of the catalyst on the CICE process varies based on its catalytic properties and stability to the etchant solution. While Au and Ag have demonstrated high anisotropy and controllable morphology (porosity, pore size, pore orientation), they are not CMOS compatible. Pt and Pd show comparable CICE process results. Use of a CMOS compatible catalyst is the first step in ensuring manufacturability of devices with CICE. Further, for a CMOS compatible catalyst, the deposition and patterning must have high yield.

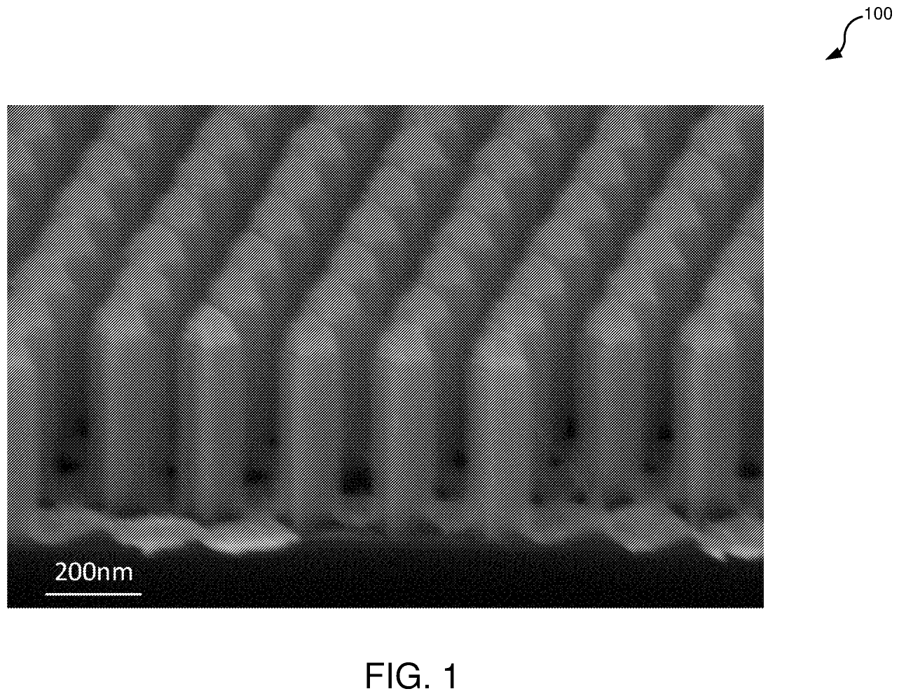

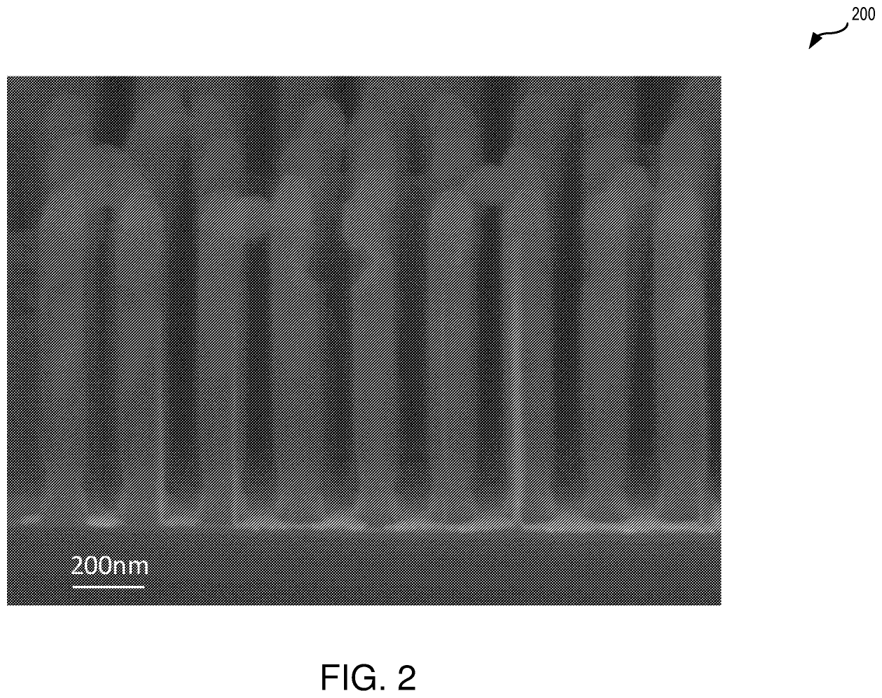

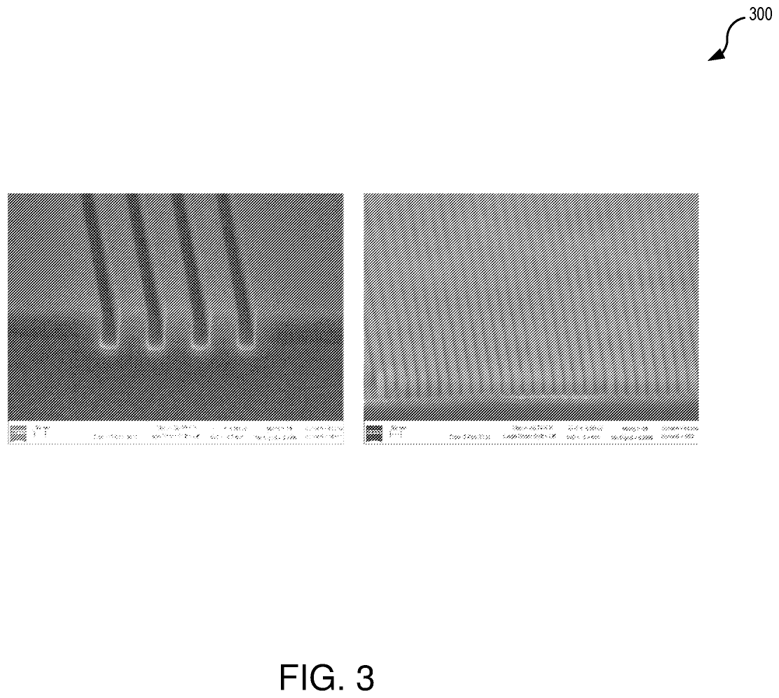

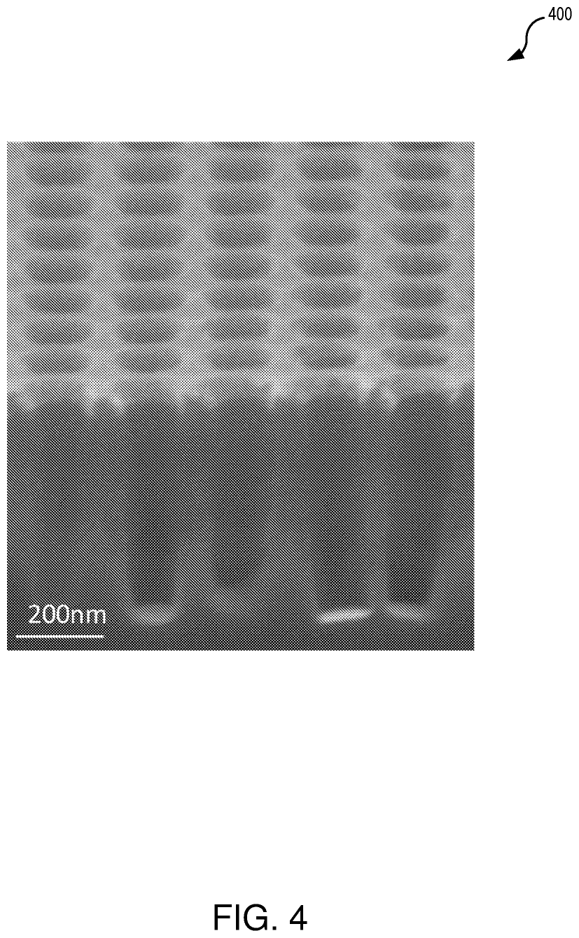

FIG. 1 illustrates an example of diamond cross-section nanowires 100 etched with a Au catalyst in accordance with some embodiments of the present technology. FIG. 2 illustrates an example of a circular cross-section nanowires 200 etched with Pd catalyst, and FIG. 3 shows nanowires 300 etched with Ru catalyst, in accordance with various embodiments of the present technology. FIG. 4 illustrates an example of circular cross-section nanoholes 400 etched with Pt catalyst in accordance with one or more embodiments of the present technology.

The deposited catalysts need to be patterned using plasma etching, wet etching, lift-off, deposition with a metal break, atomic layer etching, etc. In one embodiment, Ru is used as a catalyst for MACE. Ru can be deposited using atomic layer deposition with (a) Bis(ethylcyclopentadienyl) ruthenium(II) and O₂, NH₃ etc. as possible coreactants (b) (ethylbenzyl) (1-ethyl-1,4-cyclohexadienyl) Ru(0) precursors and O₂ as a possible coreactant, (c) thermal RuO₄ (ToRuS)/H₂, etc. Ru can also be selectively deposited in desired areas using selective ALD, with a patterned ALD-suppressing material and/or ALD-enhancing material depending on the precursors used. In one embodiment, the ALD-suppressing material is SiO₂ and ALD-enhancing material is Ti. In another embodiment, the ALD-suppressing material is Si—H and ALD-enhancing material is SiO₂.

The deposited Ru can be patterned and etched using ozone, plasma O₂, P₂/Cl₂ chemistries, with etch masks such as photoresist, polymer, imprint resist, silicon oxide, silicon nitride etc. Ru can also be etched using atomic layer etching with similar gas chemistries as for plasma etching. Ru can also be wet etched using a sodium hypochlorite mixture. After CICE with Ru, the metal can be removed using ozone, plasma O₂, O₂/Cl₂ chemistries, or wet or vapor chemistries with CMOS-compatible hypochlorite solutions.

### Catalyst Deposition

Noble and transition metals used as catalysts cannot be patterned by traditional CMOS patterning methods comprising deposition of material, lithography to define features, and plasma etching to transfer lithography pattern into desired material. This is because the catalysts typically do not form volatile compounds required for plasma etching. Further, residue from the ion milling and plasma etching can redeposit the metal within the features, leading to device failure.

The thickness of the catalyst required depends on the CICE process and the pattern to be etched. Additionally, to prevent non-uniform etch depths, the catalyst thickness can be increased to improve the rigidity of the mesh. Methods for catalyst patterning are described below.

### Selective Atomic Layer Deposition

Selective Atomic Layer Deposition (ALD) of catalyst metals such as Pt or Pd can be used to ensure that metal is only deposited in areas directly in contact with the silicon. Native silicon oxide may be used to improve surface energy gradient between the deposition areas and the lithographed resist features. FIG. 4 includes process 400 which illustrates an example of a set of steps that may be used in patterning a catalyst using selected ALD in accordance with some embodiments of the present technology.

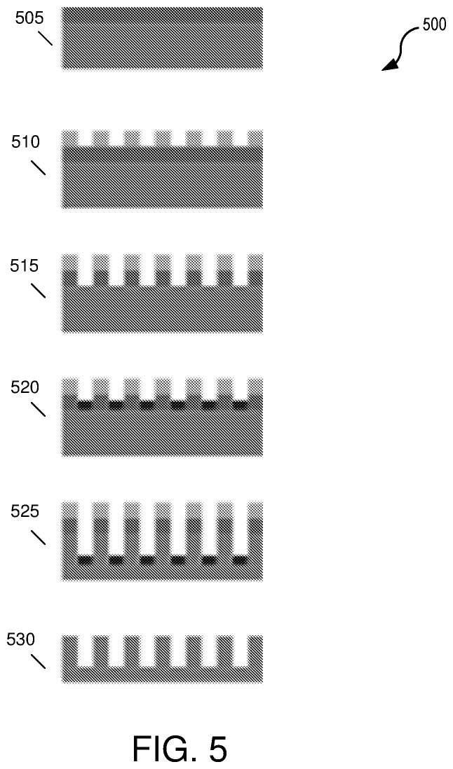

As illustrated in FIG. 5, step 505 demonstrates optical deposition of a selective blocking layer (e.g. PMMA, polyimide, carbon, etc.) on a substrate. In some embodiments, the substrate may be a Si wafer with optional layers such as epitaxial doped silicone, SiGe, or other layers based on the application. In step 510 lithography can be used to define catalyst areas. In some examples, the lithography can include one or more of photolithography imprint lithography, EUV lithography, Litho-Etch-Litho-Etch (LELE), or other types of purposed based lithography. Continuing to step 515, lithographed resist for optical lithography is developed. Additionally, descum of residual layer thickness for imprint lithography and pattern transfer into a selective blocking layer can occur to expose the silicon substrate. Furthermore, the Lithographed resist may be removed prior to selective atomic layer deposition (S-ALD). In step 520, S-ALD is applied to the catalyst material on the native oxide surface or to an oxide created by exposing the silicone substrate to an oxygen plasma. In some embodiments, ALD is not applied (or applied in insignificant amounts) to the lithographed resist and/or blocking layer. In step 525 CICE is performed and once CICE is completed, in step 530, catalyst material, the blocking layer, and/or the lithographed resist are removed.

In one embodiment, photolithography is used to create the pattern prior to selective atomic layer deposition. In this case, a multilayer stack of films are used for photolithography with an organic spin-on BARC, and the carbon hard mask used in this multilayer stack can also be used as a selective blocking layer for selective ALD.

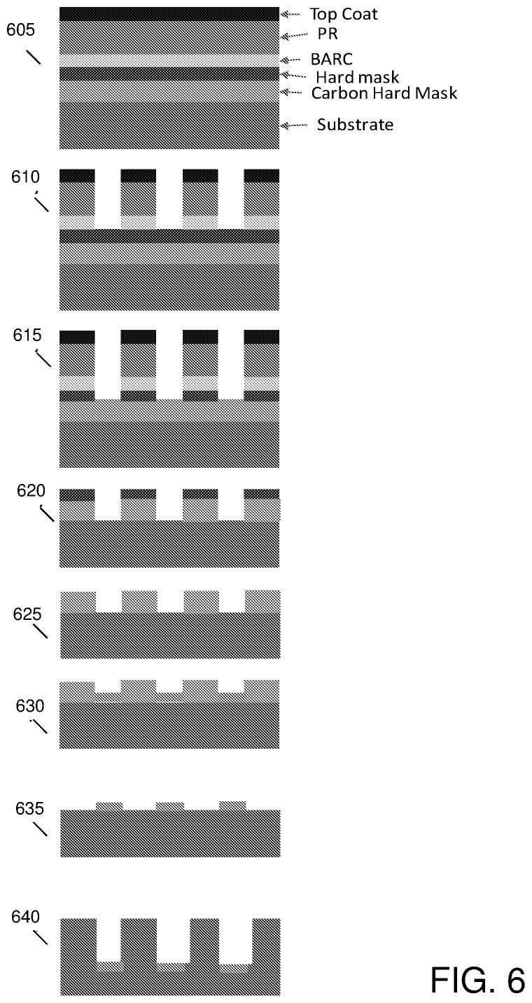

FIG. 6 includes process 600 which illustrates an example of a process flow for selective ALD after photolithography. In process step 605, photolithography is applied to a multilayer film stack. In some embodiments, the multilayer film stack includes one or more of a topcoat, a PR, a BARC, a hard mask, a carbon hard mask, and a substrate. Process 600 continues with process step 610 where photolithography is further applied to the multilayer film stack and a resist is developed. In process step 615, once the resist is developed, etching into hard mask occurs. In some embodiments, etching includes the use of silicon such as spin-on-glass or silicon dioxide. In process step 620, the photoresist is removed and etching into the carbon hard mask is performed. In some embodiments, etching the carbon hard mask may utilize CVD carbon or spin-on-carbon. In process step 625, silicon containing hard mask is removed using vapor HF. In some embodiments, the silicone containing hard mask may be removed through a plasma etch selective to carbon. After the silicone containing hard mask is removed, in process step 630, selective ALD of catalyst is performed. In process step 635, the carbon hard mask is removed. In alternative embodiment, the carbon hard mask may be left in place. In process step 640 CICE is performed.

Precursors for atomic layer deposition (ALD) are listed in the following table:

| | | | | Substrate |
|---|---|---|---|---|
| Catalyst | | | ALD | for |
| material | Precursors A | Gas B | chemistry | deposition |
| Platinum | Trimethyl(methylcyclo-pentadienyl) | Oxygen | Plasma- | SiO2, Si |
| | platinum(IV) | | enhanced, | with native |
| | | | Thermal- | oxide |
| | | | combustion | |
| | | | chemistry | |
| Palladium | Pd(hfac)₂ | Formalin, | Thermal- | |
| | | H2 | hydrogen | |
| | | | reduction | |
| | | | chemistry | |
| Gold | trimethylphosphinotrimethylgold(III) | Oxygen | Plasma | |
| TiN | Tetrakis(diethylamido) titanium(IV), | NH₃ | Plasma- | |
| | Tetrakis(dimethylamido) | | enhanced, | |
| | titanium(IV), Titanium tetrachloride, | | Thermal | |
| | Titanium(IV) isopropoxide | | | |
| TaN | Tris(diethylamido)(tert-butylamido) | Hydrogen, | Plasma- | |
| | tantalum(V) | NH₃ | enhanced, | |
| | | | Thermal | |
| Ru | Bis(ethylcyclopentadienyl) | NH₃, O₂ | Plasma, | |
| | ruthenium(II) | | Thermal- | |
| | | | combustion | |
| | | | chemistry | |
| Ir | Ir(acac)₃ | O₂ | Thermal- | |
| | | | combustion | |
| | | | chemistry | |
| Ag | Ag(fod)(PEt₃) | Hydrogen | Plasma- | |
| | | | enhanced | |
| Cu | (Cu(thd)₂); | Methanol, | Thermal- | |
| | Copper beta-diketonate: Cu(II) | ethanol, | hydrogen | |
| | 1,1,1,5,5,5- | formalin | reduction | |
| | hexafluoroacetylacetonate | | chemistry | |
| | (Cu(hfac)₂) | | | |
| Co | Co(MeCp)₂ | H₂ or NH₃ | Plasma- | |
| | | | enhanced | |
| | Bis(N-tert butyl N′- | H₂O | Thermal | |
| | ethylpropionamidinato) cobalt (II) | | | |
| W | Bis(tert-butylamido) | Si₂H₆ | Thermal- | |
| | bis(dimethylamino) tungsten(VI), | | fluorosilane | |
| | WF6 | | elimination | |
| | | | chemistry | |

### Atomic Layer Etching

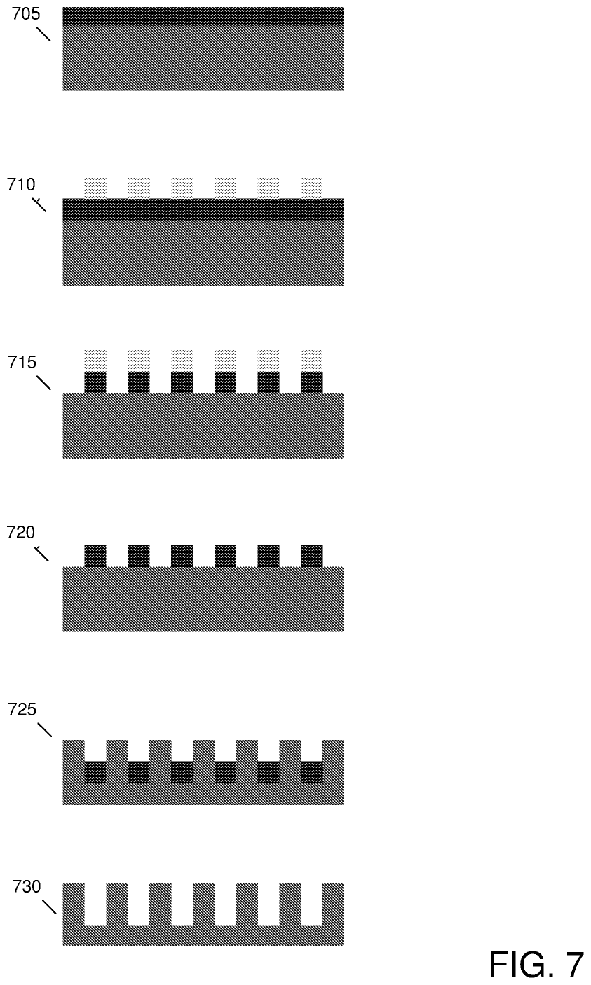

The catalyst material can be patterned based on etching away material after lithography. For instance, platinum can be etched using plasma etching with Cl₂ to form PtCl₂ at temperatures above 210° C., since PtCl₂ is volatile at those temperatures, and thus can be used as a viable method of etching the metal after deposition and lithography. Although conventional plasma etching may not produce volatile compounds for some of the catalyst materials, other methods such as Atomic Layer Etching (ALE) can be used for a gentler etch process that does not destroy the lithographed pattern. In particular, for sub-20 nm feature sizes that may be used, ALE can be used. FIG. 7 includes process 700 which illustrates an example of patterning of catalyst using ALE in accordance with some embodiments.

As illustrated in FIG. 7, step 705 calls for deposition of catalyst material on a substrate. In some embodiments, the deposition of catalyst material may utilize one or more of ALD, sputtering, electron-beam evaporation, thermal evaporation, electrodeposition, or other similar deposition methods. The substrate can be a Si wafer. In some embodiments, the substrate may include additional layers such as epitaxial doped silicon, SiGe, or other layers depending on the application of the substrate. In process step 710, the deposition of etch masks (e.g. spin-on-carbon, silicon oxide, nitride, TI, TiN, etc.) may occur followed by lithography to define catalyst areas. The lithography may be performed by photolithography, imprint lithography, EUV lithography, and/or Litho-Etch-Litho-Etch (LELE). It should be appreciated that the type of lithography used is not limited.

Once the catalyst areas are defined, in process step 715 a lithographed resist is developed for optical lithography. In some embodiments, descum of the residual layer thickness is performed for imprint lithography. Additionally, pattern transfer into the optional etch mask layer and patterning of the catalyst using plasma etching or atomic layer etching may occur. In step 720, the etch masks and the lithograph may be removed. Following step 720, in step 725, CICE is performed. Once CICE is complete, in step 730, catalyst material is removed through wet etching, plasma etching or atomic layer etching (ALE).

Typical plasma etch chemistries for etching of Pt are SF₆/Ar/O₂, SF₆/C₄F₈, Cl₂/CO, Cl₂/O₂, Cl₂/O₂F₆, H₂S, HBr, S₂Cl₂/Cl₂ and CO/NH₃. Additionally, Pd and Pt can be etched by SF₆/Ar, Cl₂/Ar and CF₄/AR gas chemistries. However, these plasma chemistries have challenges such as redeposition of etched material, high thermal requirements, and/or damage of substrate material. Atomic layer etching (ALE) is a gentler etch that can avoid these issues.

Typical etch chemistries for different catalyst materials using ALE are given below:

| | | | | Etch rate | |
|---|---|---|---|---|---|
| | | Energy | | (Angstrom/ | |
| Material | Chemistry | source | E_ion (eV) | cyc) | Directional |
| TaN | Cl₂/He | H₂/He | — | 35-70 | Yes |
| TiN | Cl₂/He | H₂/He | — | 50-73 | Yes |
| | O₃/H₂O₂, HF | Thermal | — | 0.06-0.25 | No |
| W | Cl₂ | Ar+ | 60 | 2.1 | — |
| | O₂/O₃, BCl₃, | Thermal | — | 0.34-6.3 | No |
| | HF, O₂, WF6 | | | | |
| Co | Acac | Ar⁺ | 500 | 12 | Yes |
| | Formic Acid | O₂ plasma | 200 | 28 | Yes |
| Fe | Formic Acid | O₂ plasma | 200 | 42 | Yes |
| Cu | | | | 37 | |
| Pd | | | | 12 | |
| Pt | | | | 5 | |

### Lift-Off

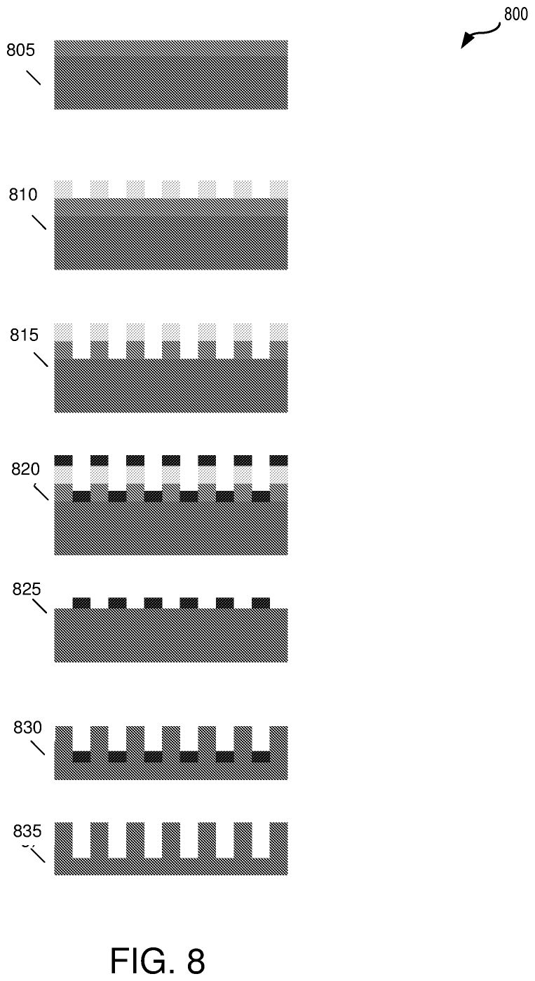

The catalyst may also be patterned using lift-off processes. FIG. 8 includes process 800 and illustrates an example of patterning of a catalyst using lift-off in accordance with some embodiments. In the embodiments shown in FIG. 8, the following steps are used. In process step 805, deposition of a lift-off layer (e.g. PVA, spin-on-glass, polyimide, etc.) on a substrate may occur. In some embodiments, the substrate may be a Si wafer. The Si wafer can include a variety of layers including an epitaxial doped silicon layer, a SiGe layer, or other types of layers depending on the application. In process step 810, catalyst areas are defined by lithography. The lithography can include photolithography, imprint lithography, EUV lithography, Litho-Etch-Litho-Etch (LELE) or other application appropriate lithographic methods.

Continuing with process step 815, a lithographed resist is developed to allow for optical lithography. Descum of the residual layer thickness may also occur. Patter transfer into the liftoff layer can be done to expose the silicone substrate, such that there is an undercut in the liftoff layer profile. The undercut may also be created in the silicon substrate using plasma etching of silicone. Once the lithograph resist is in place on the substrate, in process step 820, catalyst material can be directionally deposited by utilizing electron-beam evaporation, thermal evaporation, or other appropriate methods. In process step 825, after the catalyst material is deposited, lift off of catalyst material in areas that are not in direct contact with the silicon substrate may occur. In some embodiments, a wet etch may be used to remove the lift off layer. In step 830, CICE is performed and once complete, the catalyst material can be removed in step 835.

This liftoff process may result in yield losses and re-deposition of material, and thus has to be optimized. Ultrasonic agitation may also be used in conjunction with the lift-off process to improve lift-off yield.

Catalyst Patterning without Lift-Off

The CICE process etches into semiconductors such as silicon only in areas where the catalyst material is in contact with the silicon. This property can be used to perform the etch without lift-off. The catalyst can be deposited on top of the lithographed areas and the substrate, but only the areas in contact with the substrate are etched by CICE, without requiring liftoff. However, the catalyst on the lithographed material, such as resist, silicon nitride, chromium, aluminum oxide, etc. may also catalyze the oxidant reduction reaction and disrupt the concentrations of the etchant. This can be overcome by optimizing the CICE etchant to account for the additional catalysis.

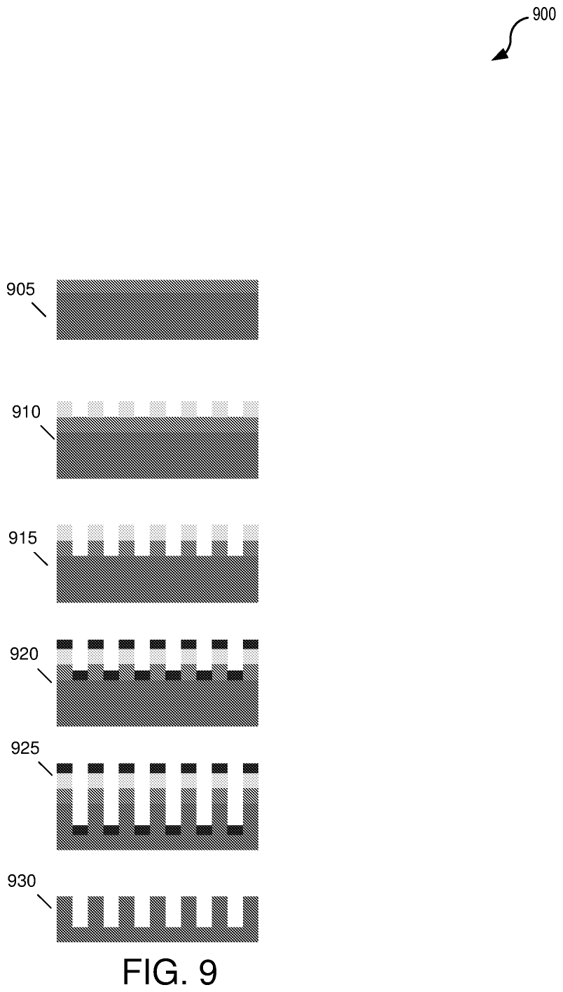

FIG. 9 includes process 900 and illustrates an example of patterning catalyst without lift-off according to various embodiments of the present technology. As illustrated in FIG. 9, some embodiments can use the following steps. In process step 905, deposition of an undercut layer stack (e.g. spin-on-glass, polyimide, spin-on-carbon etc.) on a substrate may occur. In some embodiments, the substrate may be a Si wafer. The Si wafer can include a variety of layers including an epitaxial doped silicon layer, a SiGe layer, or other types of layers depending on the application. In process step 910, lithography is used to define the catalyst areas. The lithography can include photolithography, imprint lithography, EUV lithography, Litho-Etch-Litho-Etch (LELE) or other application appropriate lithographic methods.

Continuing with process step 915, a lithographed resist is developed to allow for optical lithography. Descum of the residual layer thickness may also occur. Additionally, patter transfer into the undercut layer stack can be done to expose the silicone substrate, such that there is an undercut in the layer above the silicone substrate. The undercut may also be created in the silicon substrate using plasma etching of silicone. Once the lithograph resist is in place on the substrate, in process step 920, deposition of catalyst material can occur using methods such as electron-beam evaporation, thermal evaporating, electrodeposition or other deposition methods. In some embodiments, the deposited layer is discontinuous due to the undercut profiles. In process step 925, after the catalyst material is deposited, CICE is performed and once complete, the catalyst material, the lithographic resist, and the undercut layer material can be removed in step 930.

In one embodiment, the undercut stack comprises spin-on-carbon (or CVD carbon) and polyimide on top of the silicon. Plasma etching is tuned to have a larger lateral component for the polyimide layer than the spin-on-carbon layer, thereby creating an undercut. Silicon-containing polymers such as silspin and spin-on-Glass may also be used to improve selectivity. A silicon oxide outer shell may be present in these Si-containing-polymers which are etched away prior to or during the CICE process due to the presence of HF in the CICE etchant.

Alternatively, the undercut layer can be replaced by a short plasma etch into the silicon to create an undercut profile under a hard mask. Silicon can be etched using RIE and/or with the Bosch process. The isotropicity of the silicon can be modified by varying the etch gases, flow rates, pressure, power, DC bias, and other etch parameters.

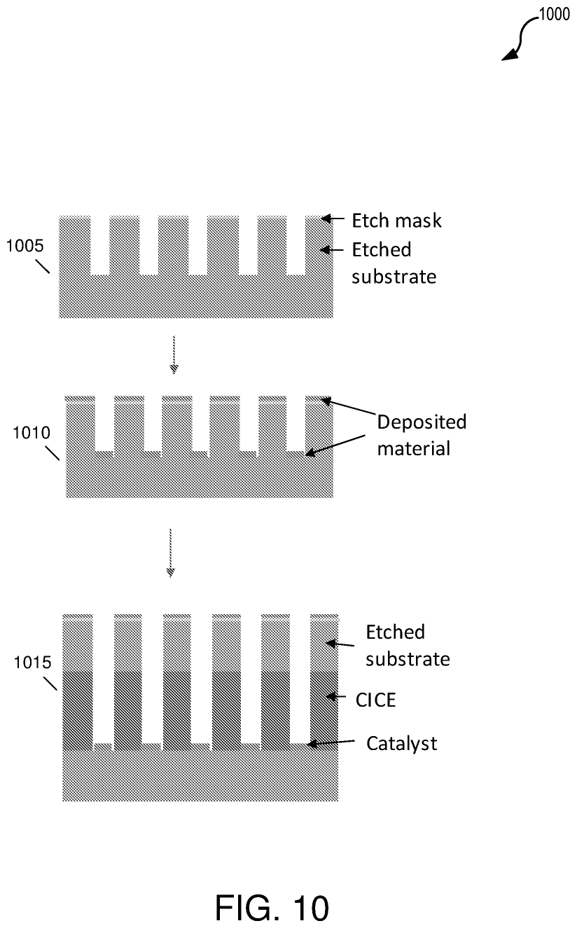

FIG. 10 illustrates an example 1000 of patterning of a catalyst by depositing catalyst material on etched features showing discontinuity in pattern according to various embodiments of the present technology. In process step 1005, the substrate is etched to a short height using plasma etching, atomic layer etching or wet etching. In process step 1010, catalyst material is deposited using physical vapor deposition, chemical vapor deposition, thermal or electron beam evaporation, etc. In process step 1015, CICE is performed to etch into the semiconducting substrate using the deposited catalyst. In one embodiment, the etch mask is carbon, chrome, etc., the initial etch is into silicon using reactive ion etching and/or deep silicon etching. The initial silicon etch profile can be isotropic to create an undercut. The catalyst deposited comprises of one or more of the following, and may also be an alloy of two or more of the following: Au, Ag, Pt, Pd, Ru, Ir, Rh, W, Co, Cu, Al, RuO₂, IrO₂, TiN, TaN, graphene, Cr, C, Mo, etc.

### Selective Electrodeposition

Another method of deposition is via electrodeposition or electroless deposition after lithography, where the metal is deposited only in areas of the substrate that are not covered by resist or an insulating material. This process may include obtaining a substrate such as a Si wafer. The Si wafer can include additional application-based layers such as an epitaxial doped silicon layer, a SiGe layer, or other type of layer. Once obtained, deposition of a thin (less than 10 nm) metal layer to improve electrical conductivity on the surface may occur. The metal layer can include one or more of Ti, TiN, Ta, TaN, W, or other application specific metals or metal compounds. Once the metal layer is deposited, an additional insulating layer such as PMMA, polyimide, or other insulating material can be deposited. Catalyst areas can then be defined though lithography (e.g. photolithography, imprint lithography, EUV lithography, Litho-Etch-Litho-Etch, etc.). A lithographed resist can then be developed for optical lithography. Alternatively, descum of the residual layer thickness for imprint lithography may occur. Once accomplished, pattern transfer into the insulating layer can be done to expose the thin metal film (if present) and/or the silicon substrate. Once exposed, selective electrodeposition or electroless deposition of the catalyst metal in areas not covered by the insulating layer material can occur.

Chemistries for electrodeposition of various catalyst metals are given in the table:

| Catalyst material | Electrolytes |
|---|---|
| Platinum | K₂PtCl₆ + HClO₄ |
| Palladium | K₂Pd(CN)4 |
| Gold | Ammonium gold sulfite, KAu(CN)₂ |
| Ru | RuCl3•xH₂O + HClO₄ |

### Catalyst Removal

After the CICE process is completed, the etchant material must be thoroughly rinsed out of the high aspect ratio structures. This can be done by increasing the temperature of the liquid to enhance replacement with rinsing media such as DI water or low surface tension liquids such as isopropyl alcohol or ethanol. Following this, catalyst material that lies at the bottom of etched high aspect ratio structures must be removed without affecting the etched structures. For instance, platinum must be etched without affecting silicon, silicon oxide, SiGe, porous silicon, porous silicon oxide, etc. Wet etchants such as aqua regia may thus not work. Plasma etching is unlikely to reach the bottom of deep and/or high aspect ratio trenches and may cause lateral etching of the fragile etched structures. Plasma etching may also redeposit the etched products. Atomic Layer Etching (ALE) is thus required to effectively remove the catalyst metal selectively.

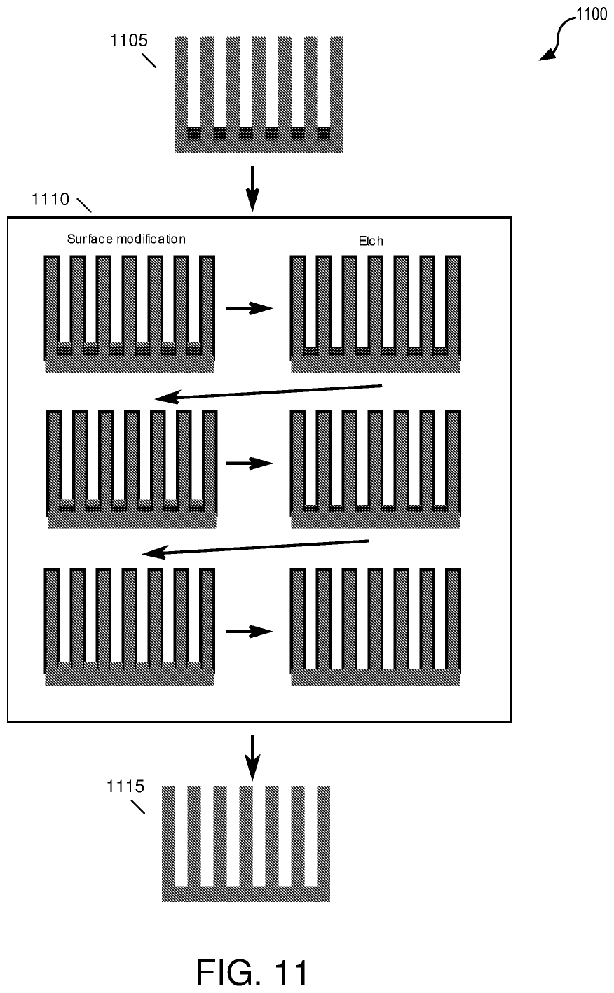

FIG. 11 illustrates an example of ALE of catalyst material in accordance with some embodiments of the present technology. FIG. 11 includes environment 1100 which further includes substrate 1105, process 1110, and semiconductor 1115. In some embodiments, semi-conductor 1105 includes a substrate with post-CICE features with catalyst material existing at the bottom of the CICE features. In process 1110, the catalyst material can be removed by an atomic layer etch of the catalyst material by repeated alternating steps of surface modification and etch. Once process 1110 is completed, semi-conductor 1115 may be produced. Semi-conductor 1115 includes a substrate with the oxide on the semiconductor high aspect ratio structures removed. In some embodiments, semiconductor 1105 and semiconductor 1115 are the same semiconductor.

In one embodiment, the catalyst is made of palladium, and atomic layer etching of palladium is performed by modifying the palladium surface using an O₂ plasma, and etching away the modified palladium surface using formic acid in liquid or vapor form. Alternatively, the surface modification is done at high temperature and no plasma, in an oxygen-rich atmosphere. In both cases, a thin layer of oxide may be formed around the silicon HAR structures as well. The thickness of the silicon oxide grown during the oxidation step may be self-limited. The formic acid etch is optimized so it does not affect the silicon oxide around the nanostructures. The silicon oxide is removed using a gentle etch such as HF vapor or atomic layer etching.

In one embodiment, the catalyst is removed using wet etching, and the leachate from the etchants is tested for trace amounts of the catalyst to be removed using elemental mapping with methods such as mass spectroscopy, ICP-MS, liquid chromatography, etc. Local areas can also be tested using EELS, XPS, XRR, etc. In one embodiment, the catalyst to be removed is gold, and the leachate is an iodide-based gold etchant. In another embodiment, the catalyst to be removed is gold, and the leachate is aqua regia, a mixture of nitric and hydrochloric acid. Alternatively, the leachate can be formic acid for catalyst such as Pt, Pd, Au, Ru, etc.

### Etchant Transport

Transport of etchant reactants and products to and from the bottom of the high aspect ratio features is critical, both for uniform etching during CICE as well as for removal of catalyst material after CICE using ALE. The maximum aspect ratios and minimum feature dimensions for ALE depend on the application for CICE. For instance, finFETs with aspect ratios of 1:100 and fin half pitch of <10 nm, or 3D NAND Flash devices with aspect ratios of 1:500 and feature sizes of 30 nm may require additional process features to enable transport of etchant material to and from the bottom of the high aspect ratio structures. This can be accomplished by one or more methods. For example, the temperature of the gases and/or the substrate is increased. Once the temperature of the gases or substrate is elevated, large “access-holes” are created for improved transport, particularly for sub-50 nm holes with aspect ratios >100. In one embodiment, micron scale holes are patterned at a 10 micron pitch to enable vertical transport of etchant gases, such that the area occupied by the access holes does not exceed more than 1% of the area of the desired device. Lateral transport to other catalyst regions is achieved by using lateral porous layers, and/or by utilizing connected catalyst mesh designs.

Alternatively, the pressure inside the pressure chamber may be increased (P>100 mT) during surface modification and etching, with high vacuums (P<10 mT) for pumping out the gasses between the ALE steps. Furthermore, introducing a neutral gas with kinetic energy directed toward the surface after the etch gases are introduced, such that the neutral gas drives/knocks the etching gases into the feature may done.

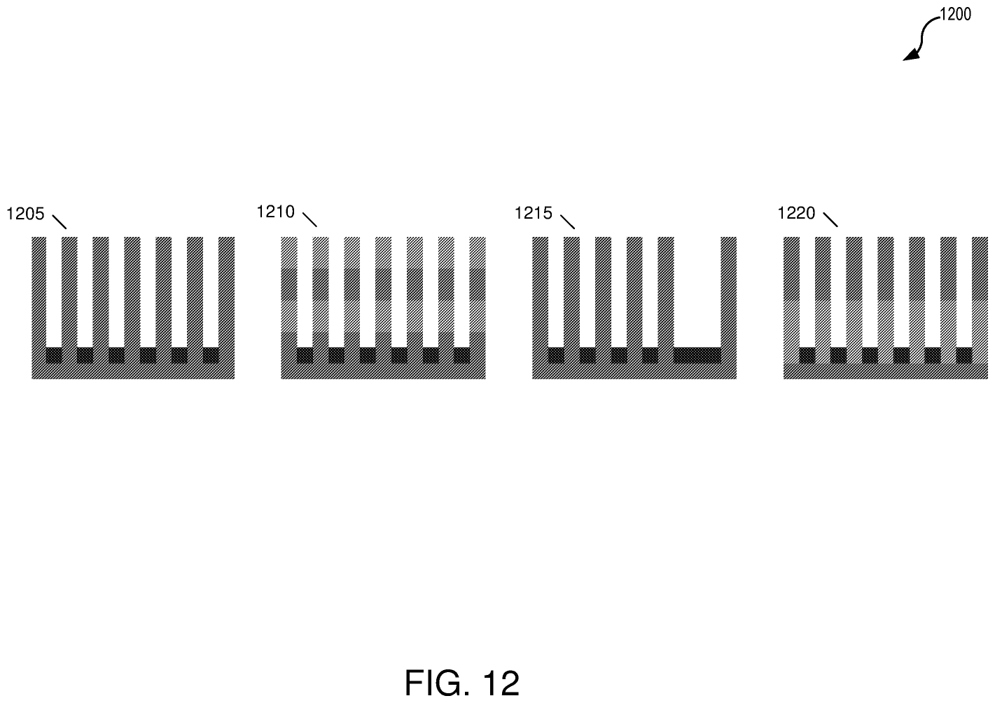

FIG. 12 illustrates an example 1200 of access of catalyst for ALE in high aspect ratio trenches and includes semiconductor nanostructures 1205, 1210, 1215, and 1220 in accordance with one or more embodiments of the present technology. Semiconductor 1205 includes bulk silicon high aspect ratio structures. Semiconductor 1210 includes alternating layers of porous and non-porous silicon HAR structures for improved transport of catalyst etchant gases. Semiconductor 1215 includes large features and connected catalyst structures for improved physical transport. Semiconductor 1220 includes intentional porous structures created at bottom of HAR structures for improved transport.

In one embodiment, for the application of 3D NAND Flash devices, CICE is used to create nanostructures with alternating layers of porous and non-porous silicon. ALE must be performed to remove the catalyst metal without affecting porous silicon, non-porous silicon, and in some embodiments, oxidized porous silicon.

In an embodiment for the application of finFETs devices, porous layers are created laterally using CICE to enhance etchant diffusion during formation of fins. These porous layers may then be oxidized and/or removed during the fabrication of gate, source, drain and dielectric components.

In another embodiment for the application of nanosheet FETs devices with alternating layers of Si and SiGe, porous layers are created laterally in some of the silicon portions of the nanosheet fins using CICE to enhance etchant diffusion. These porous layers may then be oxidized and/or removed during the fabrication of gate, source, drain and dielectric components.

In another embodiment for the application of nanosheet FET devices, CICE is used to create nanostructures with alternating layers of SiGe and Si. In this case, ALE must be performed to remove the catalyst material without affecting Si and SiGe.

In some of the ALE processes, oxidation of the catalyst is performed prior to etch. In this case, care should be taken to oxidize only the catalyst and not the nanostructures. Alternatively, a thin self-limited oxide may be grown on the nanostructures, which is removed with an HF vapor etch. In another case, selective oxidation of porous-silicon can be performed while also oxidizing the catalyst for ALE.

### Embedded Catalyst

In applications where the catalyst material does not participate in the final device, the catalyst can be removed using etching or it may be embedded within insulating material to ensure it doesn't affect the performance of the device. This can be achieved by using CICE to etch to larger depths than is required for the application. The excess depth is then utilized to create an insulating layer that isolates the catalyst.

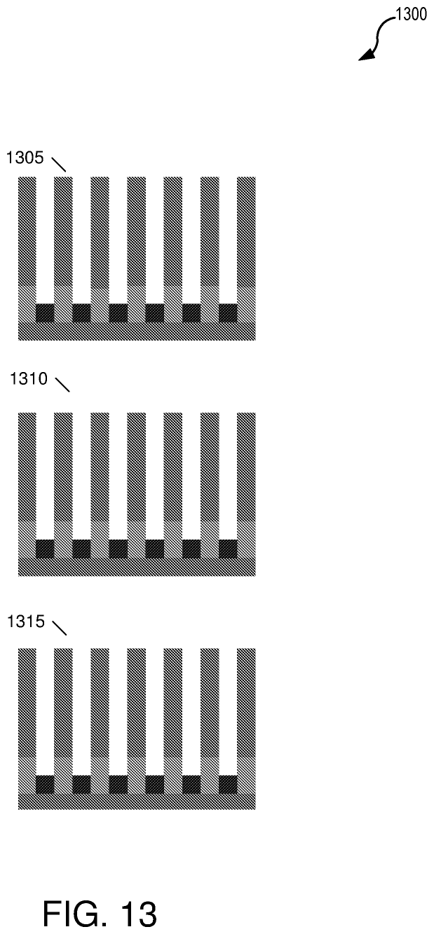

FIG. 13 illustrates an example of a process flow with an embed catalyst according to some embodiments of the present technology. FIG. 13 includes process 1300 and process steps 1305, 1310, and 1315. In process step 1305, high aspect ratio structures after CICE with a porous layer at the bottom are shown. The porous layer can be oxidized to improve insulating properties. Process step 1310 includes conformal depostition of an isulator such as SiO2 using ALD, CVD, or other similar prcocesses. Process step 1315, demonstrates timed etch back of SiO2 using vapor HF. Optical metrology can be perfomred to control etch depth monitoring by using local heating to enhance etch rates in required areas.

Alternatively, SiO₂ can be selectively deposited on the catalyst material using ALD to ensure the thickness of insulating material is uniform.

### Selective Removal of Alternating Layers

In applications such as 3D NAND, in some embodiments, alternating layers of porous-Si or oxidized porous-Si must be removed selective to silicon layers. This can be performed using HF vapor or a solution of HF and H₂O₂ or by using ALE of SiO₂. In some embodiments, alternating layers of silicon must be removed selective to tungsten or silicon oxide layers. This can be performed using ALE of Si, etching using TMAH, KOH, EDP, or other selective silicon etchants.

In applications such as Nanosheet FETs, alternating layers of SiGe must be removed selective to silicon layers. This can be performed using hydrochloric acid (HCl) or by using ALE.

### Combinatorial Catalysts

The catalyst materials used for CICE can be an alloy of different materials designed to create the desired etch characteristics for CICE, such as catalytic activity, grain size, chemical resistance to CICE etchant, ability to be patterned and removed after CICE, etc. The alloys can be deposited using a combinatorial sputter system. Alloys would include active CICE materials such as Au, Ag, Pt, Pd, Ru, Ir, W, TiN, RuO₂, IrO₂, etc. and inactive or etch retarding materials such as Mo, C, Cr, metal oxides, semiconductor oxides and nitrides.

A combinatorial sputter of varying compositions of the potential alloys can be used to optimize for the ideal catalyst material. Co-sputtering is used to create combinatorial multinary catalysts. A sputter target with the optimized catalyst composition is then created for large area CICE and volume production. In one embodiment, the catalyst comprises 1-99% Cr and the remaining portion as Ru. In another embodiment, the catalyst comprises 1-99% Carbon and the remaining portion as Ru. Other alloys include CrₓC_{y}Ru_{1-x-y}, CrₓC_{y}Pd_{1-x-y}, CrₓRu_{y}O_{1-x-y} etc.

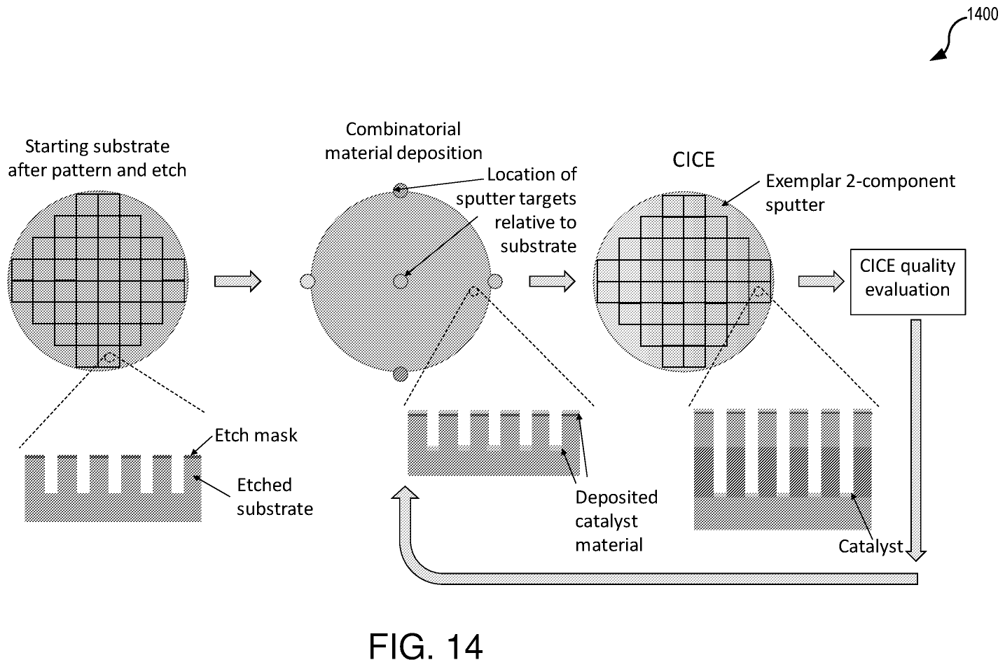

FIG. 14 illustrates an example of combinatorial material deposition 1400 in accordance with some embodiments of the present technology. In the embodiments illustrated in FIG. 14, the starting substrate is prepatterned to create short etched structures with an etch mask to enable discontinuous deposition of the catalyst material. The catalyst alloys are sputtered onto the substrate having short etched structures using co-sputtering, where the composition of the catalyst alloys depending on the location of the sputter targets relative to the wafer. The use of discontinuous deposition allows for testing of different catalyst alloys without the need for developing chemical etch recipes to pattern them. The substrate with the patterned multinary catalysts is then etched with CICE and the quality of the CICE process is evaluated at different locations to determine the best alloy. This process is repeated with different catalyst locations and compositions to determine the ideal catalyst for various applications with CICE.

### Metrology of Collapsed Features for Etch Depth and Yield Monitoring

Collapse of nanostructures can be prevented by using a ceiling and/or a low surface energy coating to increase the critical height of the features before collapse. The ceiling fabrication is done by etching the features with plasma etching or SiSE to a short, stable height; depositing the ceiling, and continuing the SiSE process. The “ceiling” can also be at a height that is along the length of the short pillars, such as at L/2, where L is the height of the short stable pillar. This gives additional support as the features are further etched and extends the maximum aspect ratio to greater than that with the ceiling on top of the short pillars. This gives structural stability to the high aspect ratio pillars and prevents collapse.

The ceiling can be deposited by angled deposition; polymer fill, etch back and ceiling deposition; or methods such as spin coating. Materials that can be used for the ceiling include polymers, sputtered/deposited semiconductors, metals and oxides that do not react with the CICE etchants, such as Cr, Cr2O3, carbon, silicon, Al2O3, etc. The ceiling can also be made porous by an additional low resolution lithography step or by a reaction to induce porosity to the ceiling material. Once the substrate is etched and the catalyst is removed, deposition of memory film or dielectric filler by methods like atomic layer deposition can be done before removal of the porous ceiling. The ceiling material could also to tuned to be non-selective to Atomic Layer Deposition (ALD) thereby preventing the pores from closing and blocking the deposition pathways. After filling the features, the ceiling is etched or polished away. ALD can also be used to close off high-aspect ratio shapes after etch to create deep holes without the use of isolated catalysts.

The deposition of a low surface tension material such as fluoropolymers can be done by chemical vapor deposition. Gases such as CF4, CHF3, CH2F2, CH4 can be used to deposit polymers using a plasma tool. In one embodiment, the passivation layer is deposited using the same process used to create a passivation layer in the Bosch process for Deep Reactive Ion Etching of Silicon. An anisotropic etch is then used to remove the passivation layer on top of the catalyst at the bottom of the nanostructures, and the sample is further etched using CICE.

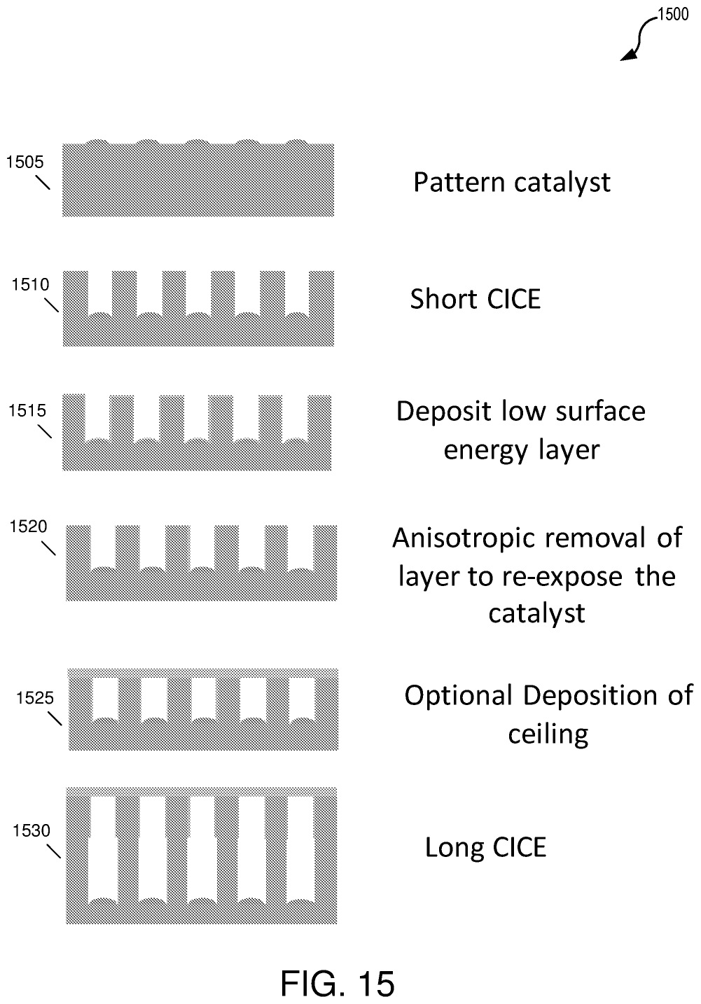

FIG. 15 illustrates an example of a process 1500 for extending critical aspect ratio of features etched with CICE in accordance with some embodiments of the present technology. In process step 1505, a catalyst is patterned using embodiments described. A short CICE process in 1510 is done to create un-collapsed nanostructures. Process step 1515 involves conformal deposition of a low surface energy layer which is removed from the top of the catalyst surface in step 1520 using anisotropic plasma etching. To further improve the critical aspect ratio of the structures before collapse, a ceiling can be deposited on top of the nanostructures in step 1525 using methods such as angled deposition or sacrificial material fill, etch back, ceiling deposition, and removal of the sacrificial material. In process step 1530, a long etch using CICE can be done to create un-collapsed nanostructures with critical heights enhanced by the low surface energy layers and ceilings.

Improvement in Aspect Ratios by using low surface tension coatings, e.g., Teflon, and an optional fixed “ceiling” to prevent collapse. Mechanics models and simulations for adhesion and collapse are used to determine the critical heights for collapse due to various forces such as gravity, adhesion to the substrate, adhesion between adjacent nanowires, and capillary effects.

Traditionally, etch uniformity is achieved by using an etch stop layer that is minimally attacked by the etch chemistry used to etch the desired material. However, for applications with high aspect ratio etch of silicon, such as for finFETs, DRAM trench capacitors and MEMS devices, a timed etch is used instead of an etch stop. Similarly, for MACE, the silicon nanostructure height is determined by a timed etch where the etchants are rinsed away to prevent further etch. Due to deviations from the predetermined etch rate due to variations in temperature, etchant concentrations, background light, etc., the exact etch time may differ from wafer to wafer. An in-situ etch monitor that has portions that are programmed to collapse at or before the target etch depth can be used to determine the etch time, thereby improving yield and uniformity.

If the yield monitor is designed to have a certain optical signature for the nominal process conditions, PCₙₒₘᵢₙₐₗ=f(γ_{s nominal}, Eₙₒₘᵢₙₐₗ, hₙₒₘᵢₙₐₗ), deviations in this optical signature, in time as well in space, would indicate deviation from the nominal process conditions. The yield monitors' optical signature, in time and space, would be tailored for each specific etch process.

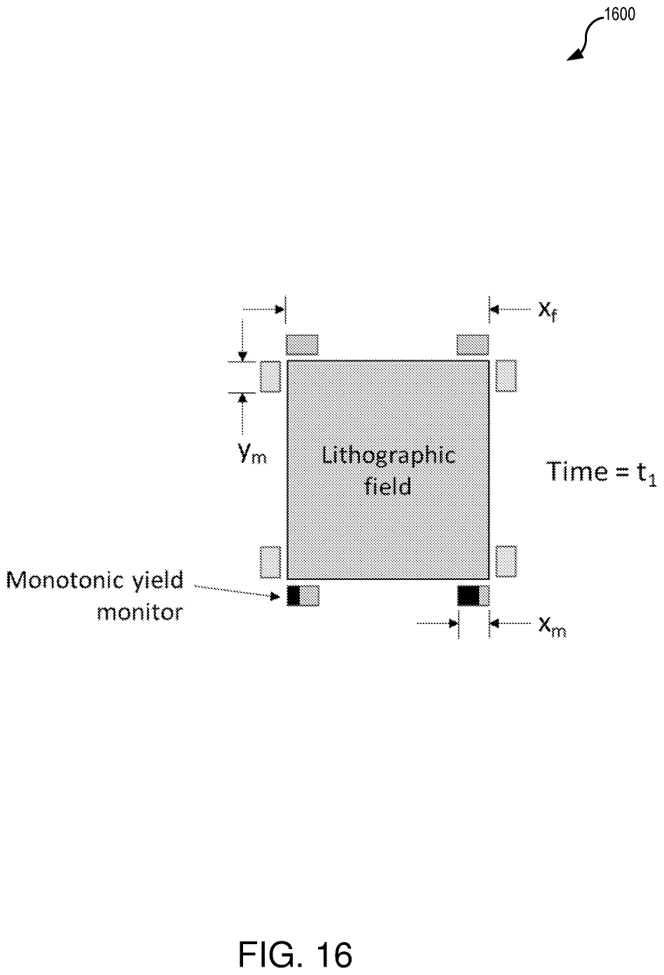

FIG. 16 illustrates an example of the area of a programmable collapse 1600 according to some embodiments of the present technology. The area of the programmable collapse is determined by the minimum resolution for optical metrology of the pillars to detect collapse. In one embodiment, the yield monitor structures comprise of multiple rows of pillars with critical dimensions varying from 5 nm to 1000 nm in steps of 5 nm, and the dimensions of the initial collapsed pillars at a certain time can determine the etch depth. Alternatively, the spacing between pillars can be varied to get similar collapse results. Such designs can also be used as yield monitors for timed-plasma etch processes. However, after nanostructure collapse, the pillars start getting etched along the sidewalls due to the directional nature of the plasma, potentially causing non-repeatable optical signatures.

### Silicon Superlattice Integration Schemes for 3D NAND Flash

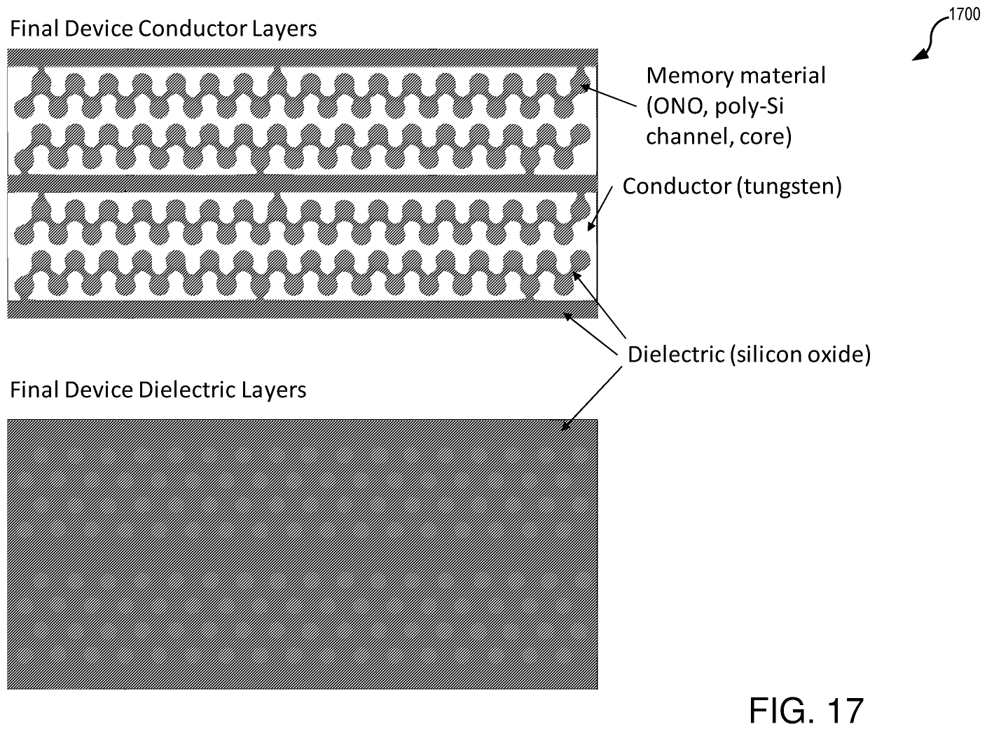

FIG. 17 illustrates an example of a silicon superlattice integration scheme 17010 in accordance with various embodiments of the present technology. The conductor layers shown below can suffer from increased resistance due to dielectric material in the “maze” portions of the layer.

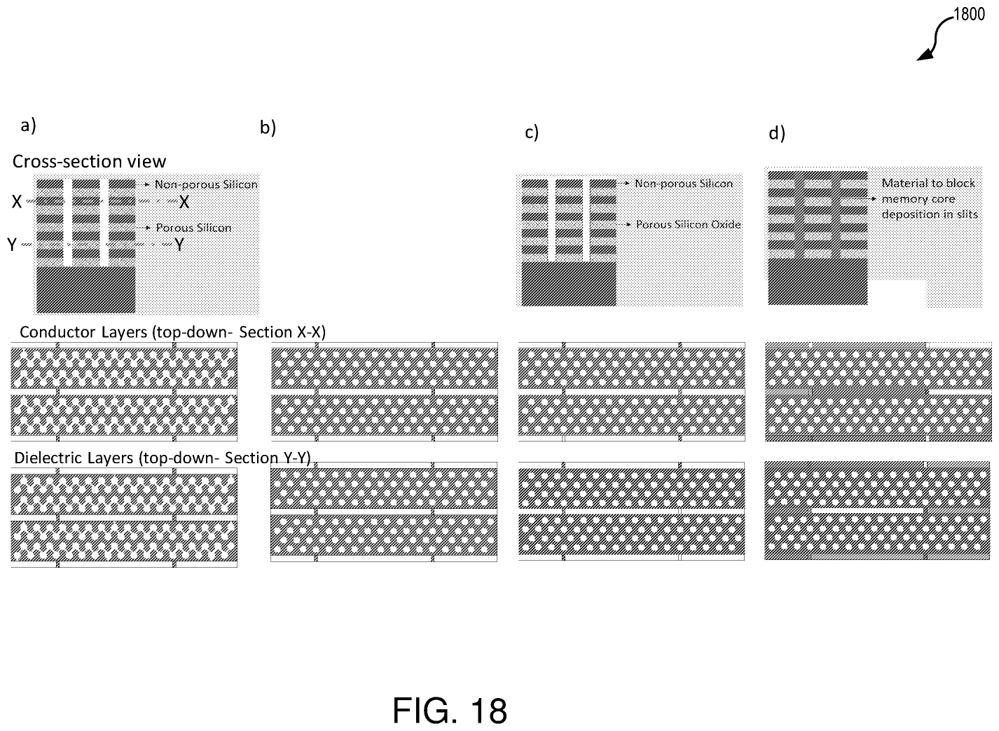

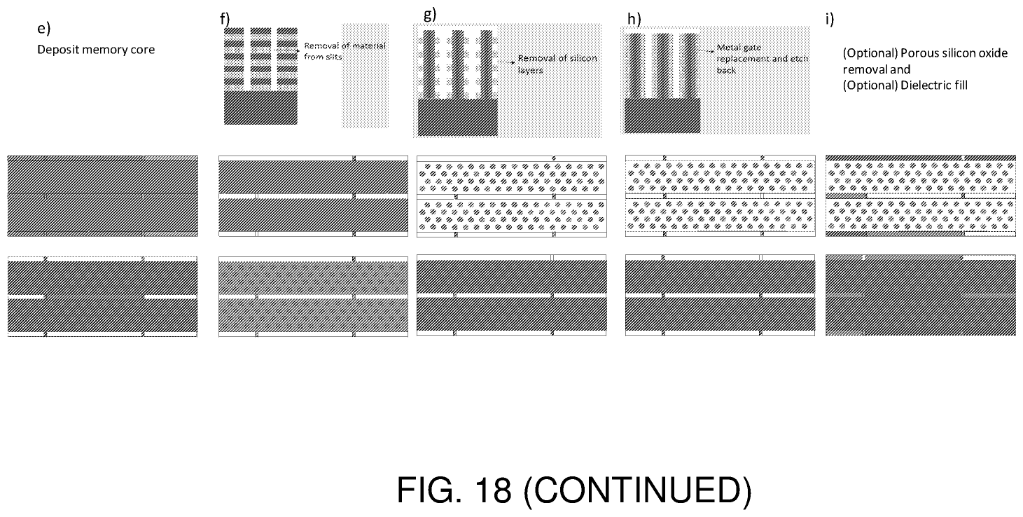

FIG. 18 illustrates an example of a process flow 1800 depicting alternative approaches to making 3D NAND Flash devices with improved conductance of the conductor (e.g. Tungsten) layers in accordance with various embodiments of the present technology. As illustrated in FIG. 18, the CICE process and subsequent catalyst removal creates semiconductor nanostructures with alternating layers of porous and non-porous silicon in step (a). A semiconductor (such as Silicon) is conformally deposited in step (b) to fill in the lithographic links. In step (c) a selective oxidation process oxidizes porous silicon and conformally deposited silicon in the porous silicon oxide layers into oxide. In step (d) a material such as polymer, carbon, silicon oxide, silicon nitride, etc. is deposited in the slits, following which, memory material such as silicon oxide, silicon nitride, poly-silicon, germanium, etc. is deposited in the holes. In step (f), the material in the slits is removed, and in step (g) silicon layers are removed selective to the porous oxide layers—including the conformally deposited amorphous or polcrystalline silicon in the silicon layers. After W is deposited and etched back in the gate replacement step (h), and optional step (i) can be performed where the porous oxide layer can be replaced with ALD filled silicon oxide, and/or the slits can be filled with a dielectric.

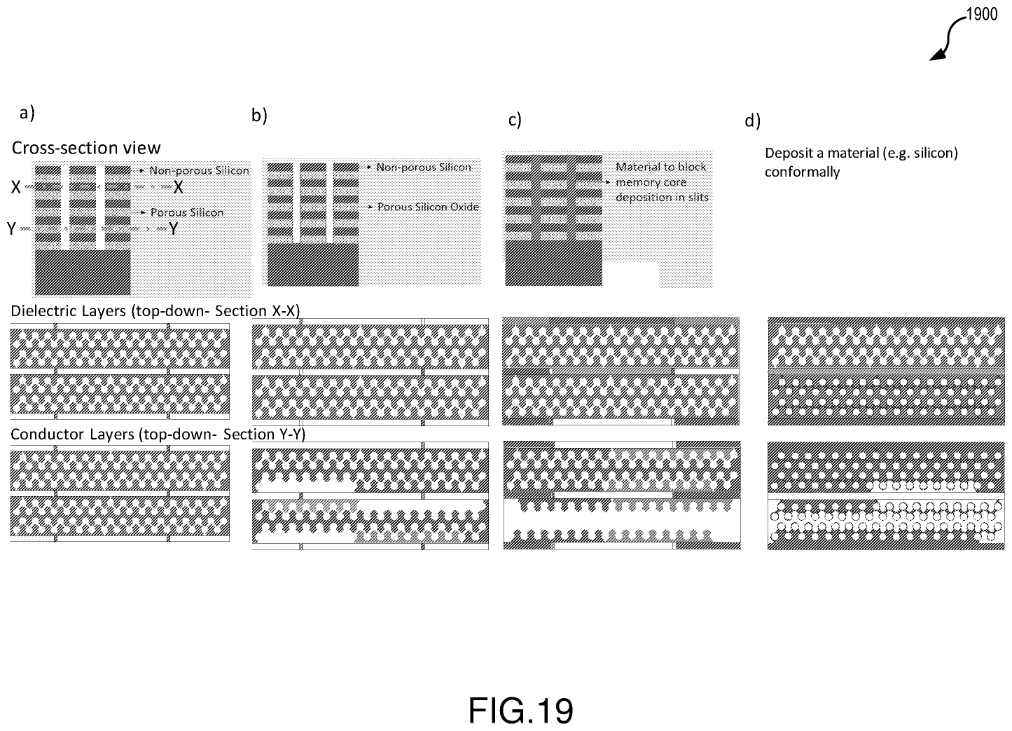

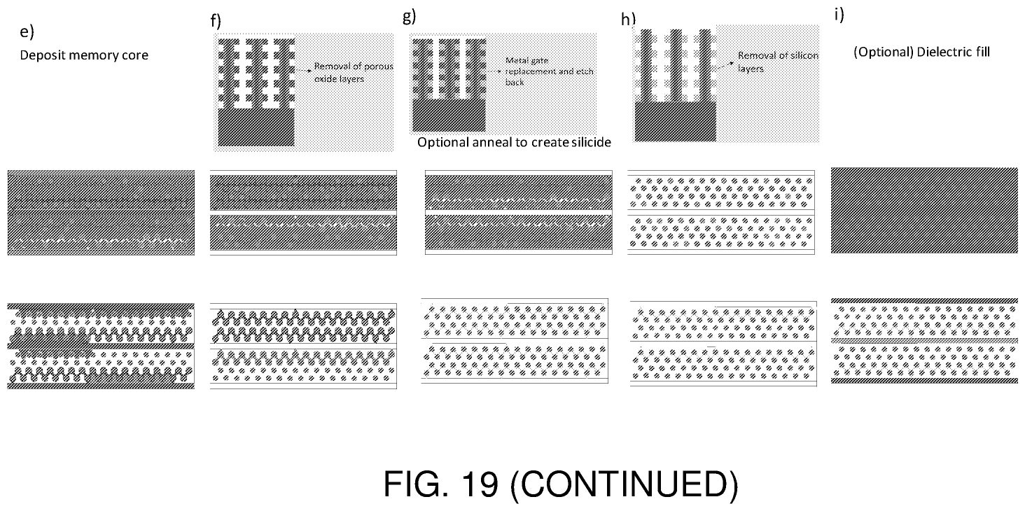

FIG. 19 illustrates an example of a process flow 1900 depicting alternative approaches to making 3D NAND Flash devices with improved conductance of the conductor (e.g. Tungsten) layers in accordance with various embodiments of the present technology. As illustrated in FIG. 19, the CICE process and subsequent catalyst removal creates semiconductor nanostructures with alternating layers of porous and non-porous silicon in step (a). In step (b) a selective oxidation process oxidizes porous silicon and conformally deposited silicon in the porous silicon oxide layers into oxide. In step (c) a material such as polymer, carbon, silicon oxide, silicon nitride, etc. is deposited in the slits. A material (such as Silicon, germanium, etc.) is conformally deposited in step (d) to fill in the lithographic links, following which, in step (e) memory material such as silicon oxide, silicon nitride, poly-silicon, germanium, etc. is deposited in the holes.

In step (f), the material in the slits is removed along with the porous oxide layers, and in step (g) W is deposited and etched back in the gate replacement step, followed by an optional anneal to get tungsten silicide in the lithographic links in the tungsten layers. This improves the conductance of the W layers as the silicided links do not impede current pathways unlike dielectric links. In step (h), silicon layers are removed selective to the tungsten (W) layers—including the conformally deposited amorphous or polycrystalline silicon in the porous oxide layers. An optional step (i) can be performed where silicon oxide or silicon oxynitride or another insulator is filled in the slots and between the W layers.

The selective oxidation of porous and/or amorphous silicon relative to non-porous silicon is done using plasma oxidation, UV oxidation, low temperature thermal oxidation, etc., where the oxidation rates are tuned using various parameters such as the temperature, oxidant flow rates (such as oxygen, ozone, water, etc.), pressure, plasma power, and oxidation times. A thin layer of non-porous silicon at the edges of the features may also get oxidized. This change in silicon layer pattern dimensions can be compensated for during the catalyst patterning and lithography steps.

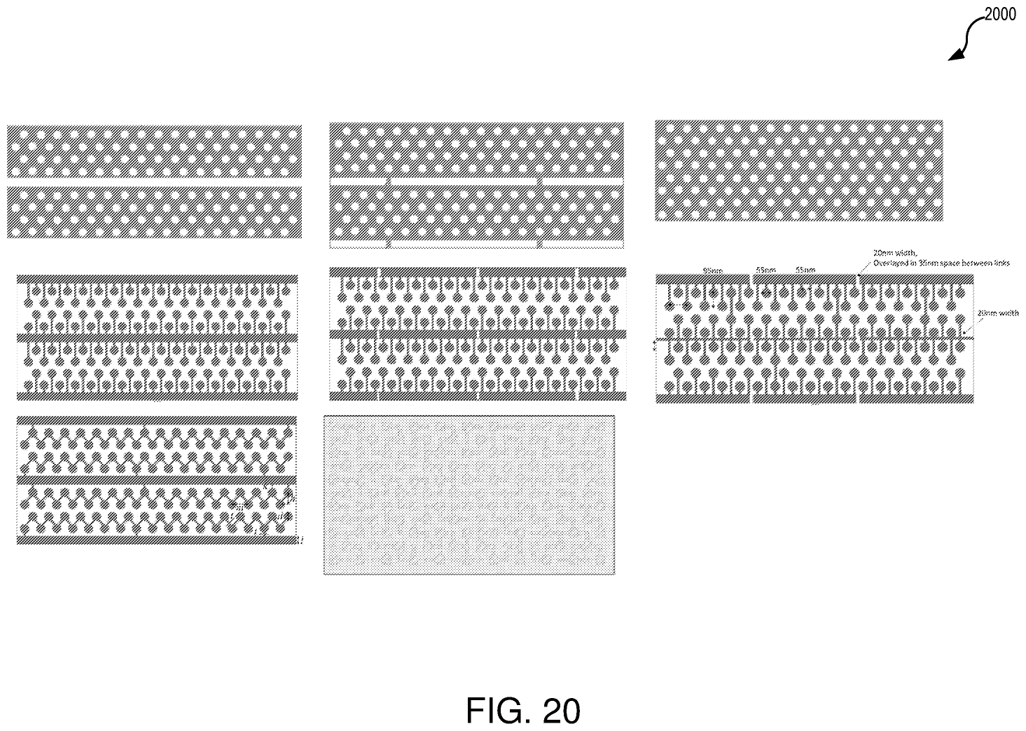

FIG. 20 illustrates examples 2000 of the catalyst patterns needed for various embodiments to create 3D NAND Flash structures. Connecting links in the catalyst patterns are provided to prevent collapse of the nanostructures during and after the CICE process, and to prevent wandering of the catalyst structures during CICE.

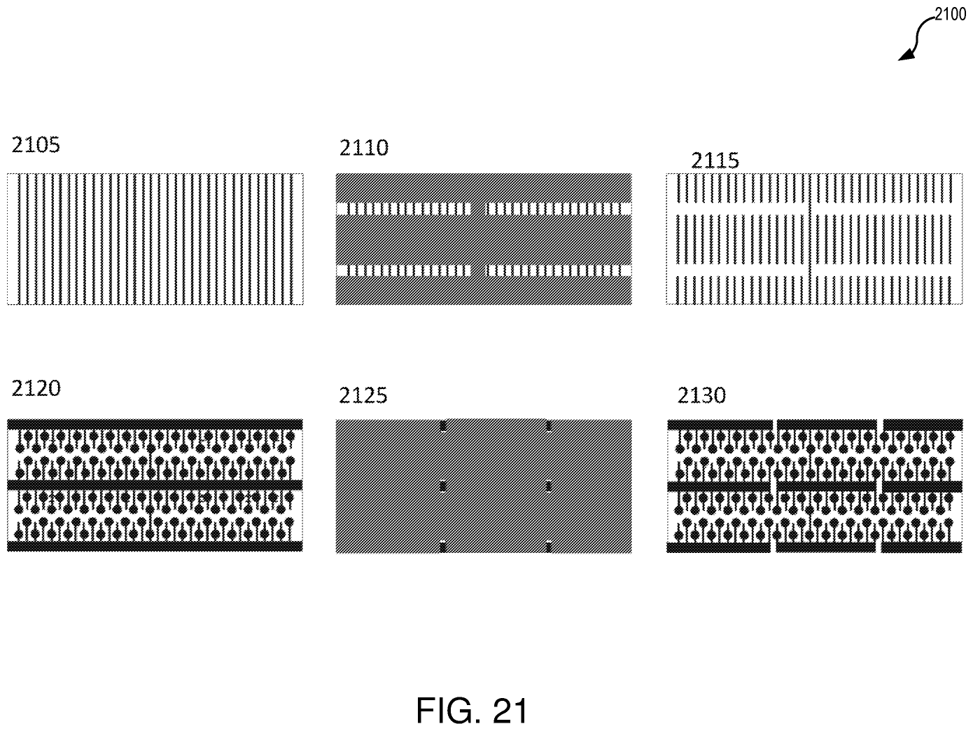

FIG. 21 illustrates an example of a lithography process flow 2100 to create catalyst patterns shown in FIG. 20. Process step 2105 involves making line/spaces for the connecting links. A cut mask (step 2110) is used to remove lines in certain regions, resulting in the links in step 2115. Dots and lines are then overlaid and patterned on the cut line spaces in step 2120. An optional cut mask is then used to pattern links in the thicker lines in step 2125 and 2130.

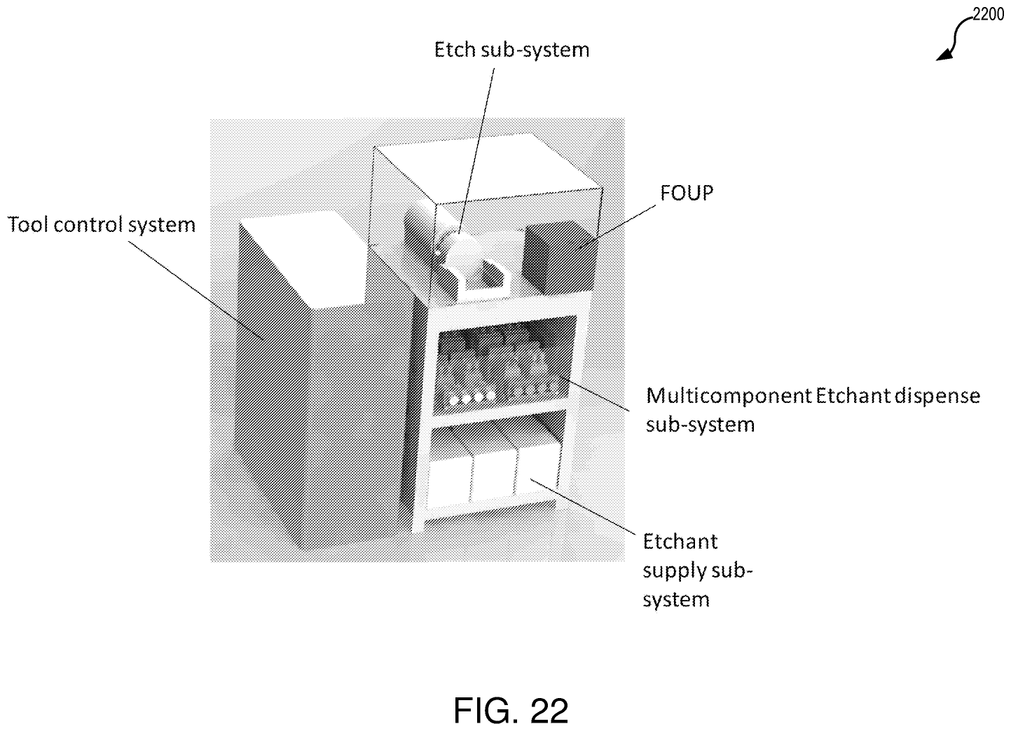

FIG. 22 illustrates an example of the CICE etch tool 2200 with various components such as the tool control system, etch sub-systems—including electric field, temperature control etc. It also consists of the etchant dispense sub-system for flow control and the etchant suppl sub-system.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, or a combination thereof. Additionally, the words “herein,” “above,” “below,” and words of similar import, when used in this application, refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

The above Detailed Description of examples of the technology is not intended to be exhaustive or to limit the technology to the precise form disclosed above. While specific examples for the technology are described above for illustrative purposes, various equivalent modifications are possible within the scope of the technology, as those skilled in the relevant art will recognize. For example, while processes or blocks are presented in a given order, alternative implementations may perform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed or implemented in parallel, or may be performed at different times. Further any specific numbers noted herein are only examples: alternative implementations may employ differing values or ranges.

The teachings of the technology provided herein can be applied to other systems, not necessarily the system described above. The elements and acts of the various examples described above can be combined to provide further implementations of the technology. Some alternative implementations of the technology may include not only additional elements to those implementations noted above, but also may include fewer elements.

These and other changes can be made to the technology in light of the above Detailed Description. While the above description describes certain examples of the technology, and describes the best mode contemplated, no matter how detailed the above appears in text, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the above Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms. For example, while only one aspect of the technology may be recited in a particular claim format (e.g., system claim, method claim, computer-readable medium claim, etc.), other aspects may likewise be embodied in those claim formats, or in other forms, such as being embodied in a means-plus-function claim. Any claims intended to be treated under 35 U.S.C. § 112(f) will begin with the words “means for”, but use of the term “for” in any other context is not intended to invoke treatment under 35 U.S.C. § 112(f). Accordingly, the applicant reserves the right to pursue additional claims after filing this application to pursue such additional claim forms, in either this application or in a continuing application.

1. An apparatus for catalyst influenced chemical etching, comprising:
a process chamber to house a semiconductor wafer;
one or more actuators configured to control environmental properties within the process chamber;
a control system to control rate of etching of the semiconductor wafer by adjusting the one or more environmental properties via the one or more actuators;
a light source to illuminate one or both sides of the semiconductor wafer; and
a rinsing station to remove the etchant.

2. The apparatus as recited in claim 1, wherein environmental properties include temperature, vapor pressure, electric field, etchant concentration, etchant composition and illumination.

3. The apparatus as recited in claim 1, wherein the rinsing station is the same as the process chamber.

4. The apparatus as recited in claim 1, further comprising a plurality of sensors to detect the etch state.

5. The apparatus as recited in claim 4, wherein the etch state comprises one or more of the following: an etch depth, a material porosity, number of alternating layers etched, electrical conductivity of doped semiconducting material in contact with an etchant, optical properties of features, and electrical properties of features measured during and/or after the etching process.

6. The apparatus as recited in claim 1, further comprising a send ahead wafer that is processed through the equipment and an offline metrology system to sense etch state of the send ahead wafer.

7. The method apparatus as recited in claim 6, wherein the offline metrology estimates process excursions noticed in the send ahead wafer.

8. The apparatus as recited in claim 1, wherein the process chamber comprises a sapphire window on one or both sides of the semiconductor wafer.

9. The apparatus as recited in claim 1, wherein the process chamber comprises one or more optic fiber cables on one or both sides of the semiconductor wafer.

10. The apparatus as recited in claim 2, wherein the sapphire window transmits illumination from a light source to the back of the substrate to create an ohmic contact.

11. The apparatus as recited in claim 1, wherein the process chamber comprises an electrode on one or both sides of the semiconductor wafer.

12. The apparatus as recited in claim 11, wherein the electrodes are designed to allow transmission of light to the one or both sides of the semiconductor wafer.

13. The apparatus as recited in claim 1, wherein the light source is a lamp with tunable wavelength and intensity.

14. The apparatus as recited in claim 1, wherein the electrolyte on the back of the electrode comprises one or more of the following: hydrogen peroxide, PVA, PLA, sulphuric acid, ammonium sulphate, or water.

15. The apparatus as recited in claim 5, wherein the etch state is determined in-situ using optical metrology on the front and on the back of the wafer.

16. The apparatus as recited in claim 15, wherein the images acquired using visible wavelengths on the front of the wafer and IR wavelengths on the back of the wafer can be used to create 3D images of the etch front at any stage of the etch process.

17. The apparatus as recited in claim 16, wherein the images are taken as snapshots at regular time intervals, with the times intervals ranging from 1 ms to 1 minute.

18-44. (canceled)

45. A method for improving reliability of catalyst influenced chemical etching, the method comprising:
providing a semiconducting material;
patterning a catalyst layer on a surface of the semiconducting material, wherein the pattern comprising one or more lithographic links; and
exposing the patterned layer to an etchant such that the lithographic links in the patterned catalyst layer enhance etchant diffusion during etch of high aspect ratio structures.

46. The method as recited in claim 45, wherein the material is one of the following:
single crystal bulk silicon wafer, a layer of polysilicon of thickness greater than 100 nm deposited on a substrate, a layer of amorphous silicon of thickness greater than 100 nm deposited on a substrate, an SOI (silicon on insulator) wafer, or a layer of epitaxial silicon of thickness greater than 100 nm on a substrate.

47. The method as recited in claim 45, wherein the material comprises alternating layers of semiconductor materials of varying doping levels and dopants, highly doped silicon and lightly doped silicon, undoped silicon and doped silicon or germanium, Silicon and SixGe1-x, differently doped silicon and/or SixGe1-x, differently doped silicon and/or Ge, or Si and Ge.

48. (canceled)

49. The method as recited in claim 45, wherein the etchant comprises at least two of the following:
fluoride species containing chemicals HF or NH4F;
oxidants H2O2, KMnO4, or dissolved oxygen;
alcohols ethanol, isopropyl alcohol, or ethylene glycol; or
protic, aprotic, polar and non-polar solvents including DI water, or dimethyl sulfoxide (DMSO).

50. The method as recited in claim 45, wherein the semiconducting material can be Ge, GaAs, GaN, Si, SiC, SiGe, InGaAs, and other Group IV, III-V, II-V elements or compounds.

51. The method as recited in claim 45, wherein the catalyst layer comprises one or more of the following: Au, Pt, Pd, Ru, Ag, Cu, Ni, W, TiN, TaN, RuO2, IrO2, or Graphene.

52-136. (canceled)
